(19) United States
(12) Patent Application Publication
(10) Pub. No.: US 2021/0184038 A1
(43) Pub. Date: Jun. 17, 2021

(54) SEMICONDUCTOR DEVICES

(71) Applicant: SAMSUNG ELECTRONICS CO., LTD., Suwon-si (KR)

(72) Inventors: Seungman Lim, Siheung-si (KR); Jaeho Park, Suwon-si (KR); Sanghoon Baek, Seoul (KR); Jisu YU, Seoul (KR); Hyeongyu You, Wanju-Gun (KR); Seungyoung Lee, Seoul (KR)

(73) Assignee: SAMSUNG ELECTRONICS CO., LTD., Suwon-si (KR)

(21) Appl. No.: 16/893,549

(22) Filed: Jun. 5, 2020

(30) Foreign Application Priority Data
Dec. 13, 2019 (KR) 10-2019-0166585

(51) Int. Cl. H01L 29/78; H01L 23/522

(52) U.S. Cl. CPC H01L 29/7855; H01L 2029/7858; H01L 23/5226

(57) ABSTRACT

A semiconductor device includes first and second active patterns, a first gate structure, first and second channels, and first and second source/drain layers. The first and second active patterns extend in a first direction, and are spaced apart in a second direction. The first gate structure extends in the second direction on the first and second active patterns. The first channels are spaced apart in a third direction on the first active pattern. The second channels are spaced apart in the third direction on the second active pattern. The first source/drain layer having a first conductivity type is formed at a side of the first gate structure to contact the first channels. The second source/drain layer having a second conductivity type is formed at a side of the first gate structure to contact the second channels. Widths in the second direction of the first and second channels are different.

### CROSS-REFERENCE TO RELATED APPLICATION

This application is based on and claims priority from Korean Patent Application No. 10-2019-0166585, filed on Dec. 13, 2019 in the Korean Intellectual Property Office, the disclosure of which is incorporated herein by reference in its entirety.

### BACKGROUND

### 1. Field

Example embodiments relate to semiconductor devices.

### 2. Description of the Related Art

In a semiconductor device including finFETs, two or three channels may be formed around one gate structure, and thus, it may have limitation to control the performance of the semiconductor device by increasing or decreasing the width of channels.

### SUMMARY

Example embodiments provide a semiconductor device having enhanced characteristics.

According to example embodiments, there is provided a semiconductor device. The semiconductor device may include first and second active patterns on a substrate, a first gate structure, first channels, second channels, a first source/drain layer, and a second source/drain layer. Each of the first and second active patterns may extend in a first direction parallel to an upper surface of the substrate, and the first and second active patterns may be spaced apart from each other in a second direction parallel to the upper surface of the substrate and crossing the first direction. The first gate structure may extend in the second direction on the first and second active patterns. The first channels may be spaced apart from each other in a third direction perpendicular to the upper surface of the substrate on the first active pattern, and each of the first channels may extend through the first gate structure in the first direction. The second channels may be spaced apart from each other in the third direction on the second active pattern, and each of the second channels may extend through the first gate structure in the first direction. The first source/drain layer may be formed on the first active pattern at each of opposite sides in the first direction of the first gate structure. The first source/drain layer may contact the first channels and have a first conductivity type. The second source/drain layer may be formed on the second active pattern at each of opposite sides in the first direction of the first gate structure. The second source/drain layer may contact the second channels and have a second conductivity type opposite to the first conductivity type. A width in the second direction of each of the first channels may be different from a width in the second direction of each of the second channels.

According to example embodiments, there is provided a semiconductor device. The semiconductor device may include a first active pattern on a substrate, first and second gate structures, first channels, second channels, a first source/drain layer, and a second source/drain layer. The first active pattern may extend in a first direction parallel to an upper surface of the substrate. The first and second gate structures may be spaced apart from each other in the first direction on the first active pattern. The first channels may be spaced apart from each other in a third direction perpendicular to the upper surface of the substrate on a first portion of the first active pattern. Each of the first channels may extend through the first gate structure in the first direction, and have a first width in a second direction parallel to the upper surface of the substrate and crossing the first direction. The second channels may be spaced apart from each other in the third direction on a second portion of the first active pattern. Each of the second channels may extend through the second gate structure in the first direction, and have a second width in the second direction different from the first width. The first source/drain layer may be formed at each of opposite sides in the first direction of the first gate structure. The first source/drain layer may be connected with the first channels, and have a first conductivity type. The second source/drain layer may be formed at each of opposite sides in the first direction of the second gate structure. The second source/drain layer may be connected with the second channels, and have the first conductivity type.

According to example embodiments, there is provided a semiconductor device. The semiconductor device may include first and second active patterns on a substrate, a first gate structure, first channels, second channels, a first source/drain layer, a second source/drain layer, a first contact plug, a second contact plug, a third contact plug, and first, second and third wirings. Each of the first and second active patterns may extend in a first direction parallel to an upper surface of the substrate, and the first and second active patterns may be spaced apart from each other in a second direction parallel to the upper surface of the substrate and crossing the first direction. The first gate structure may extend in the second direction on the first and second active patterns. The first channels may be spaced apart from each other in a third direction perpendicular to the upper surface of the substrate on the first active pattern. Each of the first channels may extend through the first gate structure in the first direction, and have a first width in the second direction. The second channels may be spaced apart from each other in the third direction on the second active pattern. Each of the second channels may extend through the first gate structure in the first direction, and have a second width in the second direction different from the first width. The first source/drain layer may be formed on a portion of the first active pattern at each of opposite sides in the first direction of the first gate structure. The first source/drain layer may contact the first channels, and have a first conductivity type. The second source/drain layer may be formed on a portion of the second active pattern at each of opposite sides in the first direction of the first gate structure. The second source/drain layer may contact the second channels, and have a second conductivity type opposite to the first conductivity type. The first contact plug may be formed on the first gate structure. The second contact plug may be formed on the first source/drain layer. The third contact plug may be formed on the second source/drain layer. The first, second and third wirings may be electrically connected to the first, second and third contact plugs, respectively.

The semiconductor device in accordance with example embodiments may be a multi-bridge channel field effect transistor (MBCFET) including first and second channels spaced apart from each other in the vertical direction and extending through the first and second gate structures. The widths of the first and second channels included in an NMOS transistor and a PMOS transistor may be adjusted such that the performance of the MBCFET may be optimized in response to the consumer's needs.

### BRIEF DESCRIPTION OF THE DRAWINGS

FIGS. 1A, 1B, 1C, 2, 3, 4, and 5 are plan views and cross-sectional views illustrating a semiconductor device in accordance with example embodiments.

FIGS. 6 to 35 are plan views and cross-sectional views illustrating a method of manufacturing a semiconductor device in accordance with example embodiments.

FIGS. 36 to 38 are a plan view and cross-sectional views illustrating a semiconductor device in accordance with example embodiments.

FIGS. 39 to 41 are a plan view and cross-sectional views illustrating a semiconductor device in accordance with example embodiments.

FIG. 42 is a circuit diagram illustrating a one-bit flip-flop in accordance with example embodiments.

FIGS. 43A to 43D illustrate layouts of standard cells corresponding to the one-bit flip-flop of FIG. 42 in accordance with example embodiments.

FIG. 44 is a circuit diagram illustrating a multi-bit flip-flop in accordance with example embodiments.

FIG. 45 illustrates a layout of a standard cell corresponding to the two-bit flip-flop of FIG. 44, in accordance with example embodiments.

FIG. 46 is a circuit diagram illustrating a multi-bit flip-flop in accordance with example embodiments.

FIG. 47 illustrates a layout of a standard cell corresponding to the two-bit flip-flop of FIG. 46, in accordance with example embodiments.

### DESCRIPTION OF EMBODIMENTS

A semiconductor device and a method of manufacturing the same in accordance with example embodiments will be described more fully hereinafter with reference to the accompanying drawings.

It will be understood that when an element or layer is referred to as being “over,” “above,” “on,” “connected to” or “coupled to” another element or layer, it can be directly over, above, on, connected or coupled to the other element or layer or intervening elements or layers may be present. In contrast, when an element is referred to as being “directly over,” “directly above,” “directly on,” “directly connected to” or “directly coupled to” another element or layer, there are no intervening elements or layers present. Like numerals refer to like elements throughout.

Spatially relative terms, such as “beneath,” “below,” “lower,” “under,” “on,” “over,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

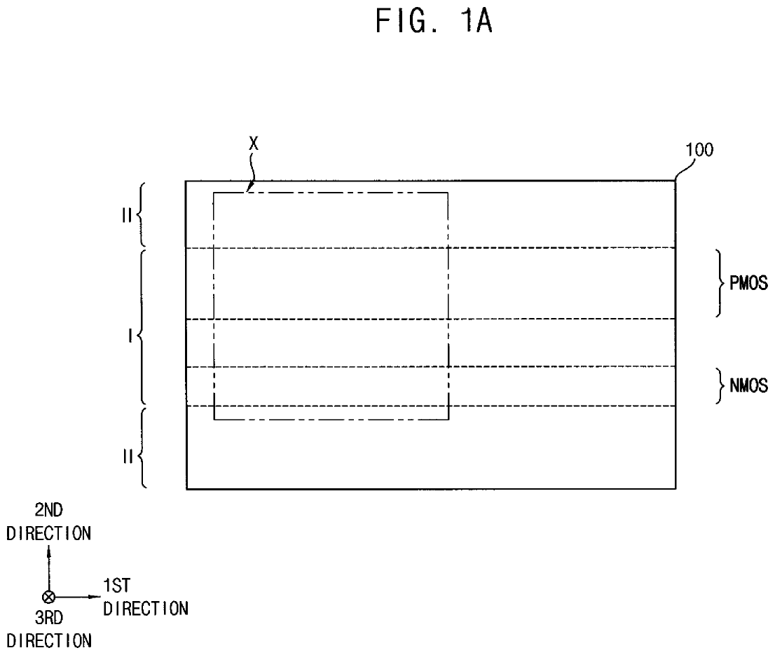

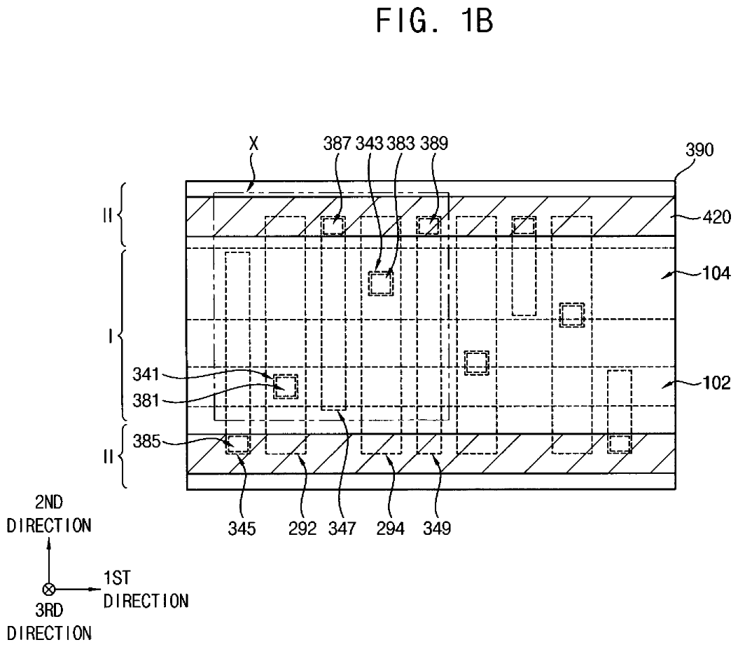

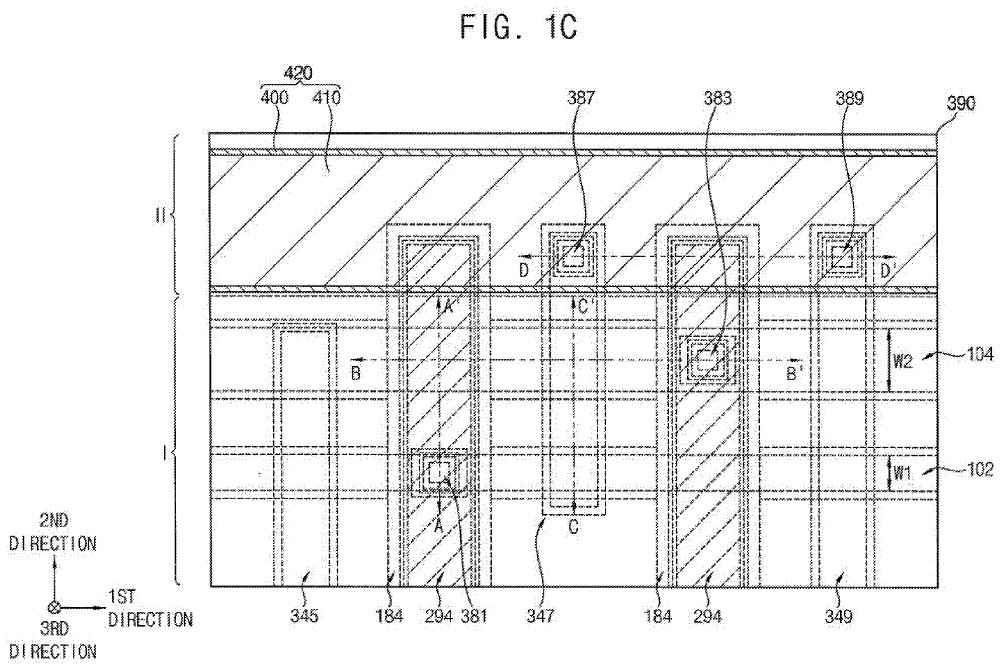

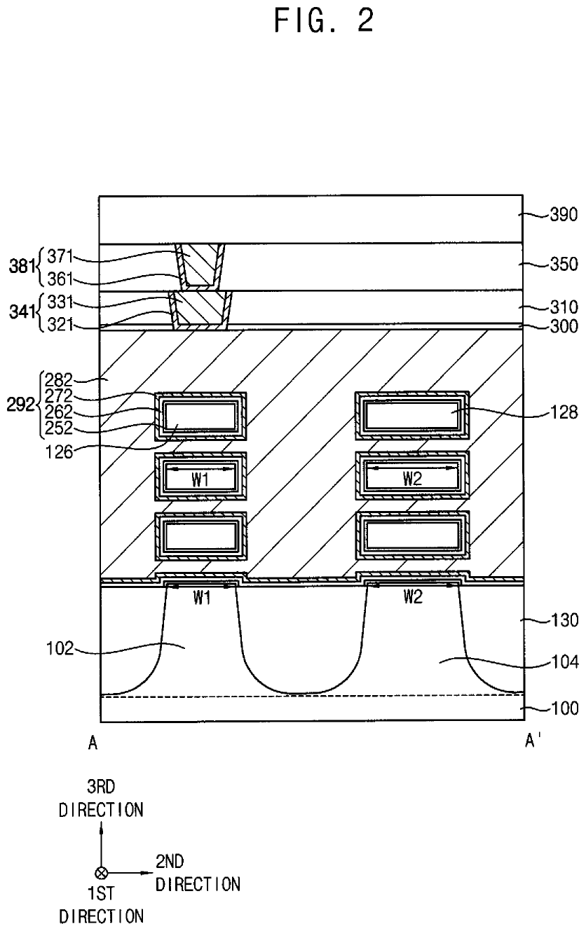

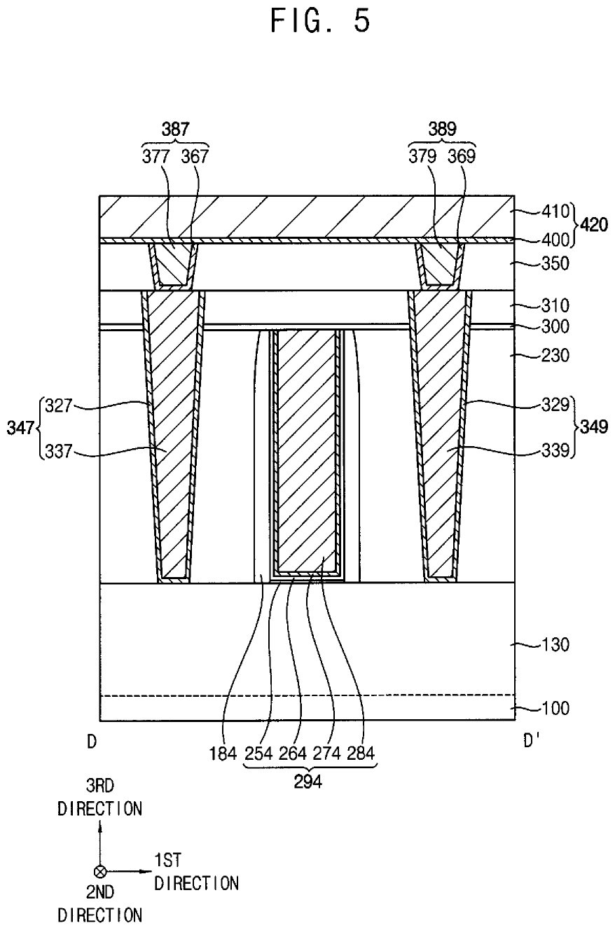

FIGS. 1A, 1B, 1C, 2, 3, 4, and 5 are plan views and cross-sectional views illustrating a semiconductor device in accordance with example embodiments. FIGS. 1A, 1B and 1C are the plan views, and FIGS. 2 to 5 are cross-sectional views taken along lines A-A′, B-B′, C-C′ and D-D′, respectively, of FIG. 1C.

FIG. 1A illustrates regions of a substrate, FIG. 1B illustrates layouts of main elements of the semiconductor device, and FIG. 1C is an enlarged plan view of a region X of FIG. 1B. In FIG. 1B, only layouts of gate structures, contact plugs, vias, and power rails are shown in order to avoid complexity of the drawing.

Hereinafter, two directions substantially parallel to an upper surface of the substrate and crossing each other may be referred to as first and second directions, respectively, and a direction substantially perpendicular to the upper surface of the substrate may be referred to as a third direction. In example embodiments, the first and second directions may be substantially perpendicular to each other.

Referring to FIG. 1A, the semiconductor device may be formed on a substrate 100 including first and second regions I and II.

The substrate 100 may include a semiconductor material, e.g., silicon, germanium, silicon-germanium, etc., or III-V semiconductor compounds, e.g., GaP, GaAs, GaSb, etc.

In example embodiments, the first region I may be a cell region in which cells may be formed, and the second region II may be a power rail region in which power rails for providing various voltages, e.g., source voltages, drain voltages, ground voltages, etc., may be formed. In example embodiments, the second region II may extend in the first direction, and a plurality of second regions II may be spaced apart from each other in the second direction.

The first region I may be disposed between neighboring ones of the second regions II in the second direction to be connected thereto. That is, opposite sides of the first region I in the second direction may be connected to the second regions II. Hereinafter, each of the first and second regions I and II may be referred to not only a portion of the substrate 100 but also a corresponding space over and under the portion of the substrate 100.

In example embodiments, the first region I may include a positive-channel metal oxide semiconductor (PMOS) region and a negative-channel metal oxide semiconductor (NMOS) region, which may be disposed in the second direction.

Referring to FIGS. 1B, 1C, 2, 3, 4 and 5, the semiconductor device may include first and second active patterns 102 and 104, first and second gate structures 292 and 294, first and second semiconductor patterns 126 and 128, and first and second source/drain layers 222 and 224, and may further include first and second gate spacers 182 and 184, first and second inner spacers 212 (not shown) and 214, an isolation pattern 130, and first to fourth insulating interlayers 230, 310, 350 and 390. Additionally, the semiconductor device may include first to fifth contact plugs 341, 343, 345, 347 and 349, first to fifth vias 381, 383, 385, 387 and 389, a power rail 420 and wirings.

Referring to FIG. 2, each of the first and second active patterns 102 and 104 may protrude from the substrate 100 in the third direction, and may extend in the first direction. In the drawings, one first active pattern 102 and one second active pattern 104 are shown, however, the inventive concept may not be limited thereto. That is, a plurality of first active patterns 102 may be spaced apart from each other in the second direction, and a plurality of second active patterns 104 may be spaced apart from each other in the second direction. The first and second active patterns 102 and 104 may be formed by partially etching an upper portion of the substrate 100, and thus, may include substantially the same material as the substrate 100.

The isolation pattern 130 may be formed on opposite sidewalls in the second direction of the first and second active patterns 102 and 104. The isolation pattern 130 may include an oxide, e.g., silicon oxide.

In example embodiments, an upper surface of the first active pattern 102 may have a first width W1 in the second direction, and an upper surface of the second active pattern 104 may have a second width W2 in the second direction that may be greater than the first width W1. A width in the second direction of the first active pattern 102 may gradually increase from the upper surface toward a lower surface thereof, and a width in the second direction of the second active pattern 104 may gradually increase from the upper surface toward a lower surface thereof.

A plurality of first semiconductor patterns 126 may be formed to be spaced apart from each other in the third direction from the upper surface of the first active pattern 102, and a plurality of second semiconductor patterns 128 may be formed to be spaced apart from each other in the third direction from the upper surface of the second active pattern 104. In the drawings, three first semiconductor patterns 126 at three levels, respectively, and three second active patterns 128 at three levels, respectively, are shown. However, the inventive concept may not be limited thereto, and thus, the number of each of the first and second active patterns 126 and 128 in the third direction is not limited to three.

In example embodiments, the first semiconductor pattern 126 may have a width in the second direction substantially equal to the first width W1, and the second semiconductor pattern 128 may have a width in the second direction substantially equal to the second width W1.

In example embodiments, a ratio of the second width W2 with respect to the first width W1 may be equal to or less than 3.

In example embodiments, the first and second widths W1 and W2 may be equal to or less than about 50 nm.

In example embodiments, each of the first and second semiconductor patterns 126 and 128 may be a nano-sheet or nano-wire including a semiconductor material, e.g., silicon, germanium, etc. In example embodiments, the first and second semiconductor patterns 126 and 128 may serve as channels of transistors, and may be referred to as first and second channels, respectively.

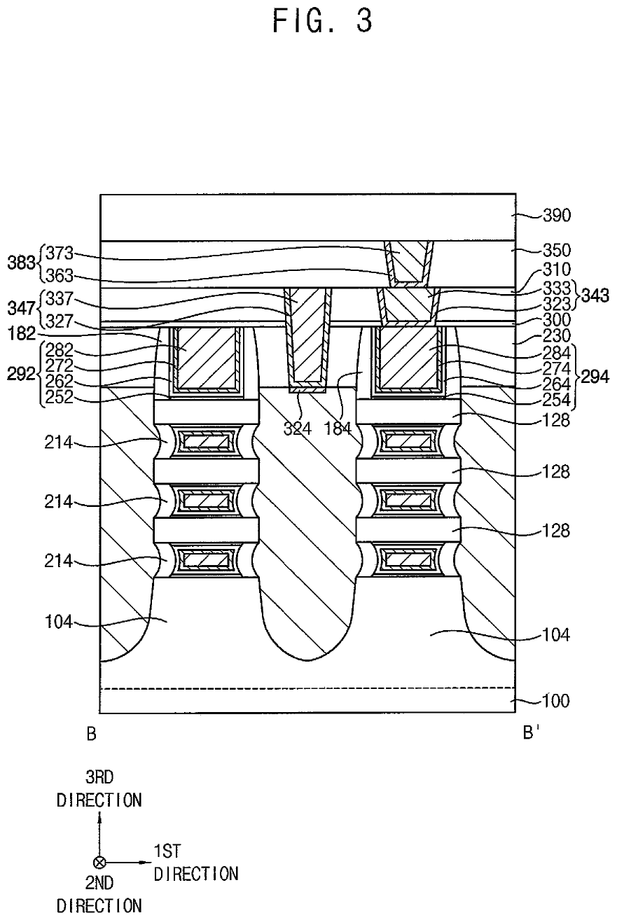

Referring to FIGS. 2 and 3, the first and second gate structures 292 and 294 may be formed on the substrate 100, and may surround central portions in the first direction of the first and second semiconductor patterns 126 and 128. In the drawings, each of the first and second gate structures 292 and 294 is formed on the first and second semiconductor patterns 126 and 128 on one first active pattern 102 and one second active pattern 104, however, the inventive concept may not be limited thereto. That is, each of the first and second gate structures 292 and 294 may extend in the second direction on the substrate 100 having the first and second active patterns 102 and 104 and the isolation pattern 130 thereon, and may be formed on the first and second semiconductor patterns 126 and 128 on a plurality of first active patterns 102 and a plurality of second active patterns 104.

In the drawings, one first gate structure 292 and one second gate structure 294 are formed on the substrate 100, however, the inventive concept may not be limited thereto. Thus, a plurality of first gate structures 292 may be spaced apart from each other in the first direction, and a plurality of second gate structures 294 may be spaced apart from each other in the first direction.

The first and second gate structures 292 and 294 may include first and second interface patterns 252 and 254, first and second gate insulation patterns 262 and 264, first and second workfunction control patterns 272 and 274, and first and second gate electrodes 282 and 284 on surfaces of the first and second semiconductor patterns 126 and 128 or the upper surfaces of the first and second active patterns 102 and 104, respectively.

The first and second interface patterns 252 and 254 may be formed on the upper surfaces of the first and second active patterns 102 and 104 and the surfaces of the first and second semiconductor patterns 126 and 128, respectively. The first and second gate insulation patterns 262 and 264 may be formed on surfaces of the first and second interface patterns 252 and 254 and inner sidewalls of the first and second gate spacers 182 and 184 and the first and second inner spacers 212 and 214, respectively. The first and second workfunction control patterns 272 and 274 may be formed on the first and second gate insulation patterns 262 and 264, respectively. The first and second gate electrodes 282 and 284 may be formed in spaces between the first semiconductor patterns 126 and between the second semiconductor patterns 128, respectively, and spaces between the first inner spacers 212 and between the second inner spacers 214 on an uppermost one of the first semiconductor patterns 126 and an uppermost one of the second semiconductor patterns 128, respectively.

The first and second interface patterns 252 and 254 may include an oxide, e.g., silicon oxide, and the first gate insulation patterns 262 and 264 may include a metal oxide having a high dielectric constant, e.g., hafnium oxide, tantalum oxide, zirconium oxide, etc. The first and second workfunction control patterns 272 and 274 may include, e.g., titanium nitride, tantalum nitride, tungsten nitride, aluminum oxide, etc. The first and second gate electrodes 282 and 284 may include a metal, e.g., titanium, aluminum, etc., an alloy of the metal, or a nitride or carbide of the metal.

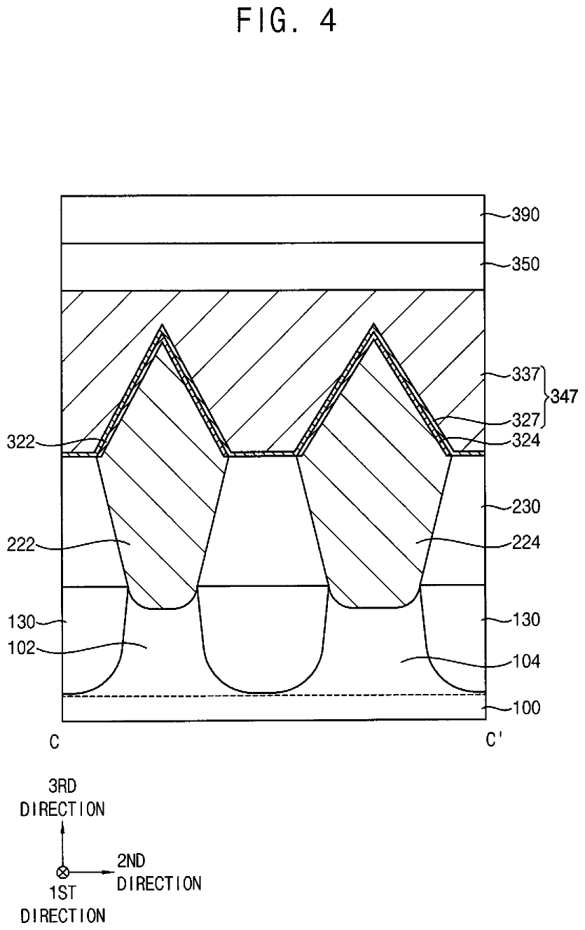

The first and second gate electrodes 292 and 294 may be electrically insulated from the first and second source/drain layers 222 and 224 shown in FIG. 4, respectively, by the first and second gate spacers 182 and 184 and the first and second inner spacers 212 and 214, respectively.

The first and second gate spacers 182 and 184 may be formed on opposite sidewalls in the first direction of upper portions of the first and second gate structures 292 and 294, respectively. The first and second inner spacers 212 and 214 may be formed on opposite sidewalls in the first direction of lower portions of the first and second gate structures 292 and 294, respectively.

Each of the first and second gate spacers 182 and 184 may include a nitride, e.g., silicon oxynitride, silicon oxycarbonitride, etc., and the first and second inner spacers 212 and 214 may include a nitride, e.g., silicon nitride.

Each of the first and second source/drain layers 222 and 224 may extend in the third direction on the first and second active patterns 102 and 104, respectively, and contact sidewalls in the first direction of the first and second semiconductor patterns 126 and 128, respectively, to be connected thereto.

In example embodiments, the first source/drain layer 222 may include single crystalline silicon doped with n-type impurities or single crystalline silicon carbide doped with n-type impurities, and the second source/drain layer 224 may include single crystalline silicon-germanium doped with p-type impurities.

As the first source/drain layer 222 includes n-type impurities, portions of the first and second gate structures 292 and 294 adjacent thereto, the first source/drain layer 222 and each of the first semiconductor patterns 126 serving as channels may form an NMOS transistor. As the second source/drain layer 224 includes p-type impurities, portions of the first and second gate structures 292 and 294 adjacent thereto, the second source/drain layer 224 and each of the second semiconductor patterns 128 serving as channels may form a PMOS transistor. A plurality of first semiconductor patterns 126 may be spaced apart from each other in the third direction and a plurality of second semiconductor patterns 128 may be spaced apart from each other in the third direction, and thus, the semiconductor device described above may be a multi-bridge channel field effect transistor (MBCFET) device.

The first insulating interlayer 230 may surround sidewalls of the first and second gate spacers 182 and 184, and may be formed on the first and second source/drain layers 222 and 224. The first insulating interlayer 230 may include an oxide, e.g., silicon oxide.

The first and second contact plugs 341 and 343 may extend through the second insulating interlayer 310 to contact upper surfaces of the first and second gate structures 292 and 294, respectively, and the third to fifth contact plugs 345, 347 and 349 may extend through the first and second insulating interlayers 230 and 310 to contact upper surfaces of the first and second source/drain layers 222 and 224.

The first to fifth vias 381, 383, 385, 387 and 389 may extend through the second and third insulating interlayers 310 and 350 to contact upper surfaces of the first to fifth contact plugs 341, 343, 345, 347 and 349, respectively.

The power rail 420 may extend through the fourth insulating interlayer 390 to contact upper surfaces of the third to fifth vias 385, 387 and 389, and the wirings may extend through the fourth insulating interlayer 390 to contact upper surfaces of the first and second vias 381 and 383.

As illustrated above, the semiconductor device may include a plurality of first channels, formed of the first semiconductor patterns 126, each of which may extend through the first gate structure 292, and a plurality of second channels, formed of the second semiconductor patterns 128, each of which may extend through the second gate structure 294, and thus, may be an MBCFET. Widths of the first and second channels, that is, the widths W1 and W2, included in the NMOS transistor and the PMOS transistor, respectively, of the MBCFET may be controlled so that the performance of the MBCFET may be optimized.

For example, if an MBCFET having a high performance is needed, the widths of the channels of the NMOS transistor and the PMOS transistor may have a large value. Alternatively, if an MBCFET having a high efficiency is needed, the widths of the channels of the NMOS transistor and the PMOS transistor may have a proper value.

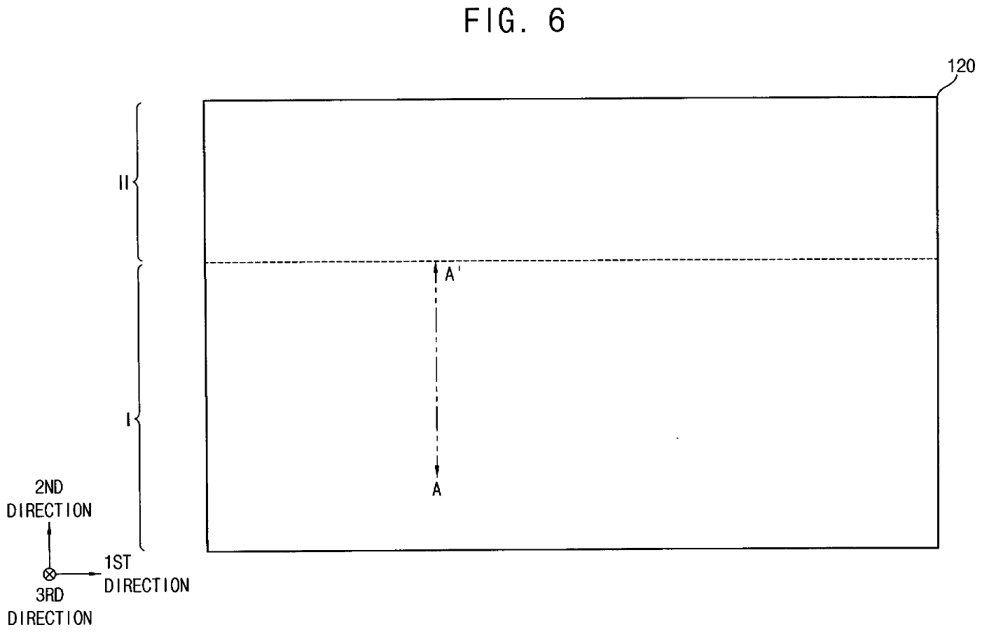

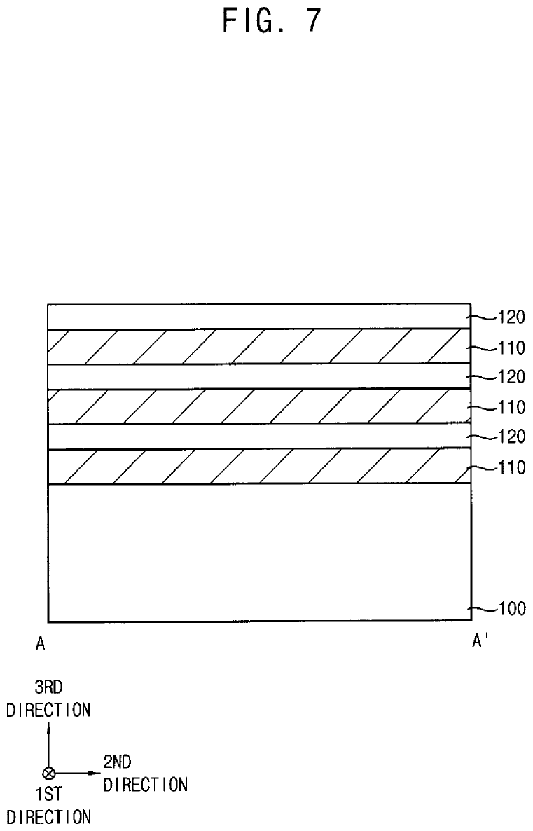

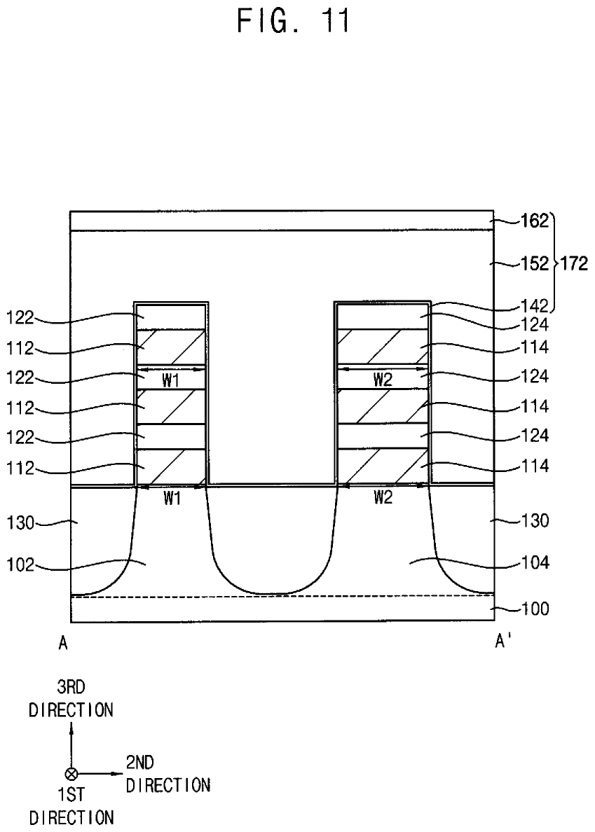

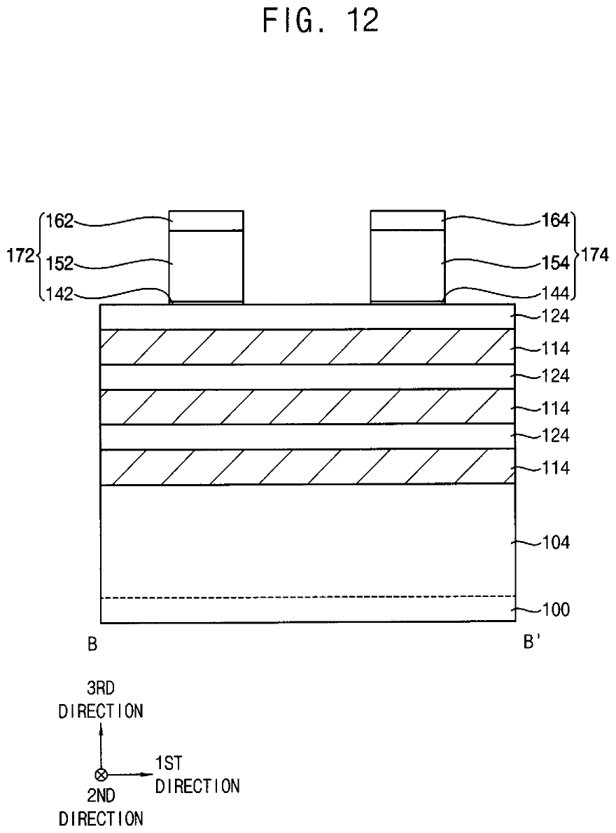

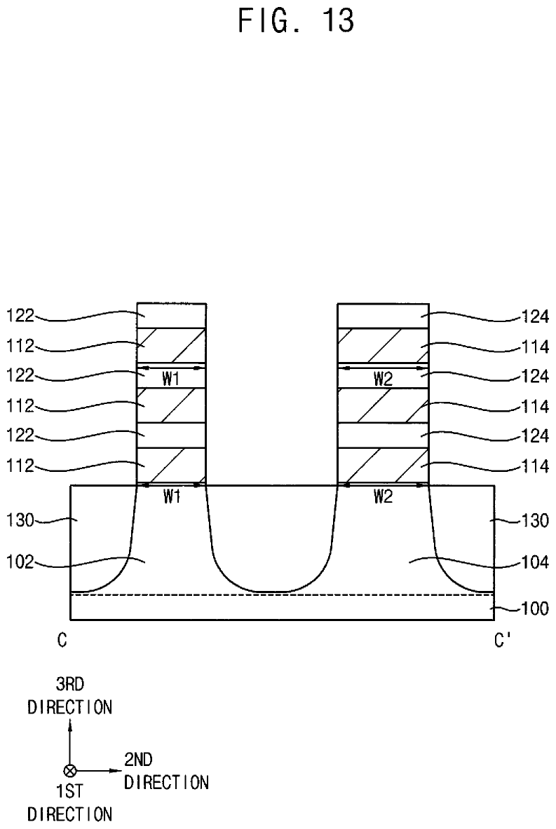

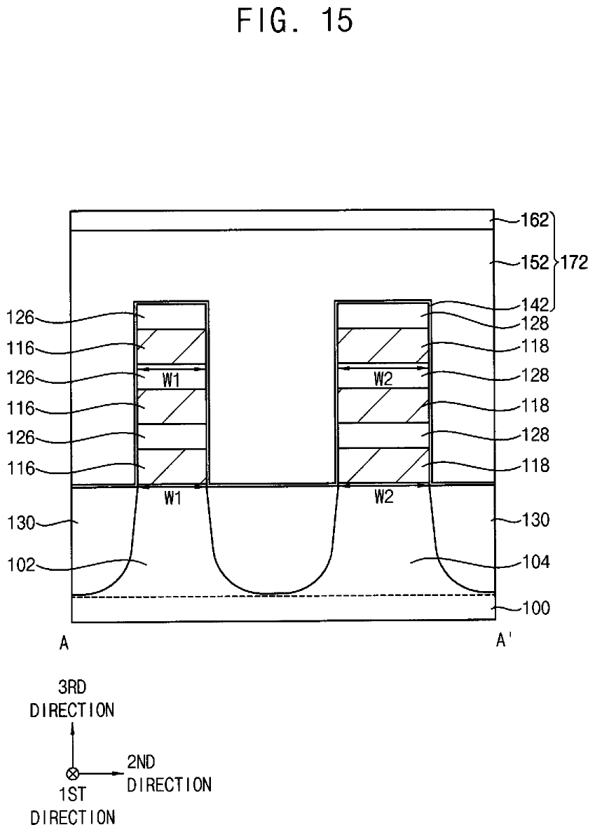

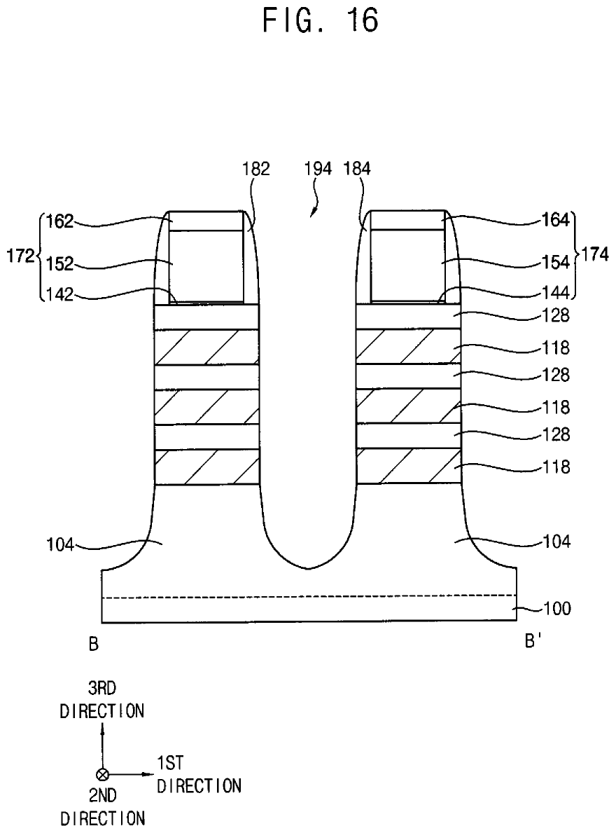

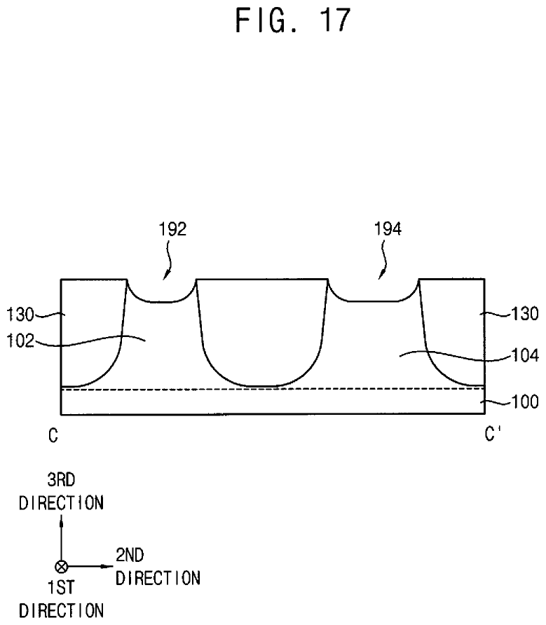

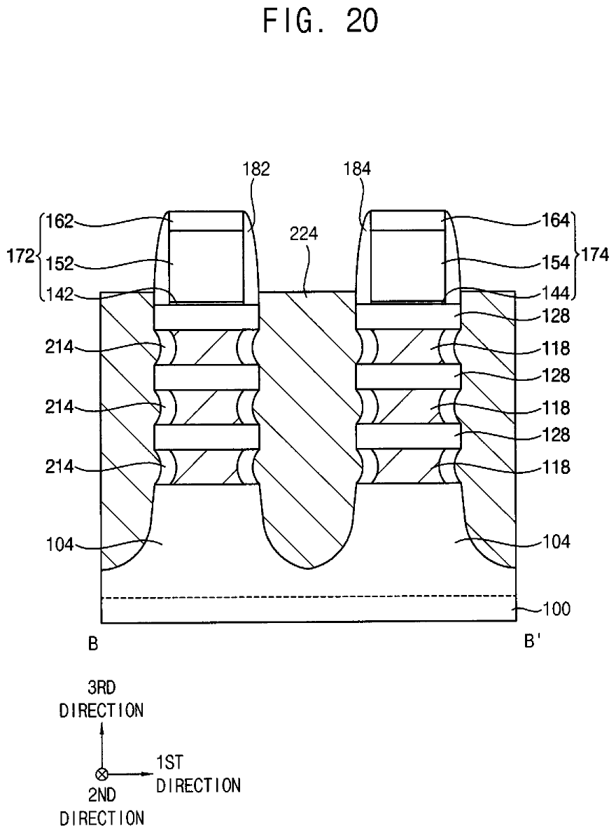

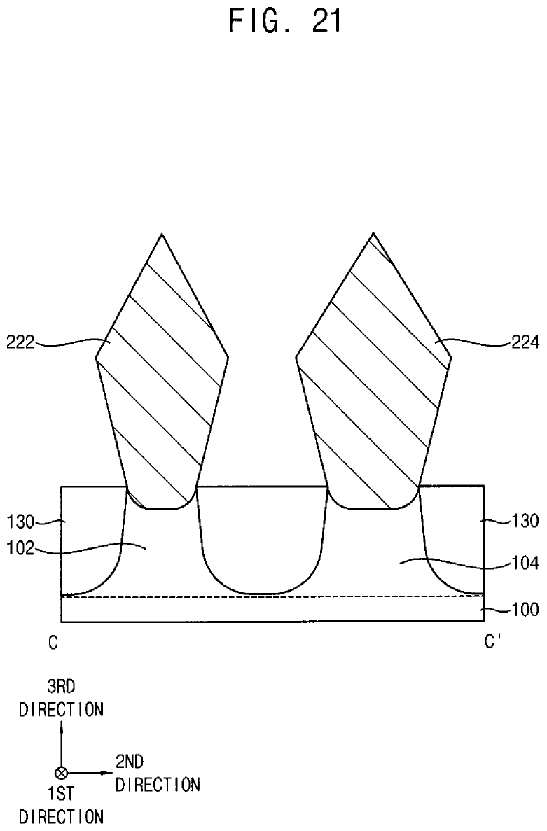

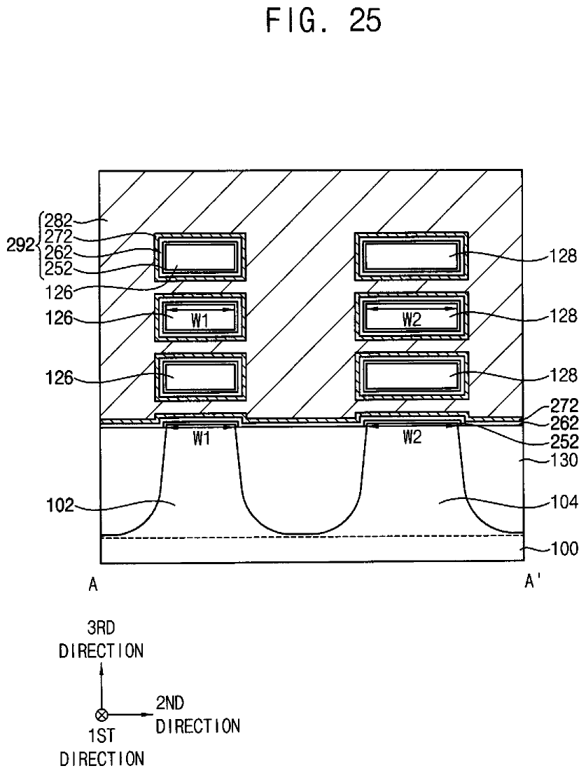

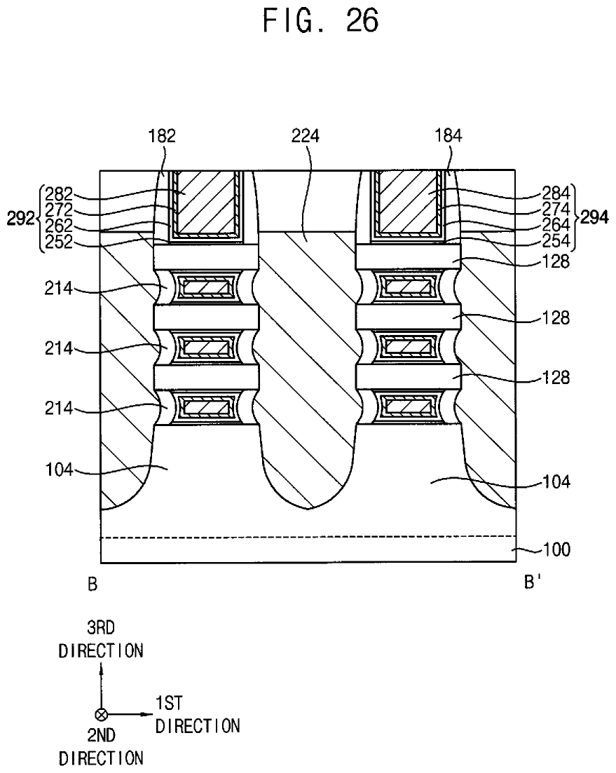

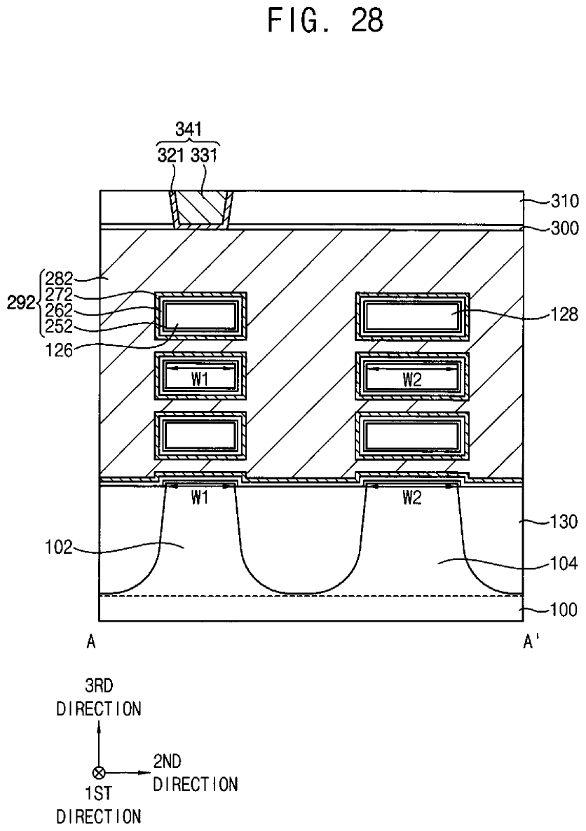

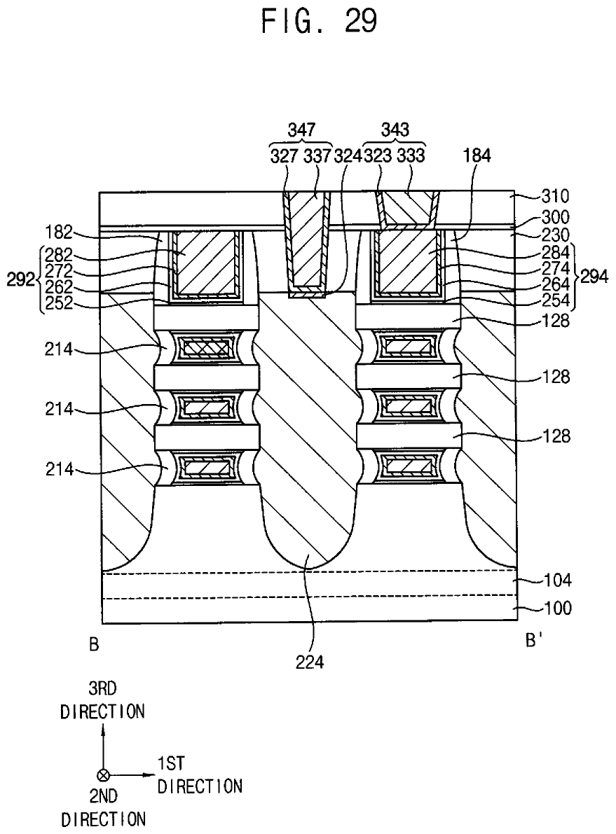

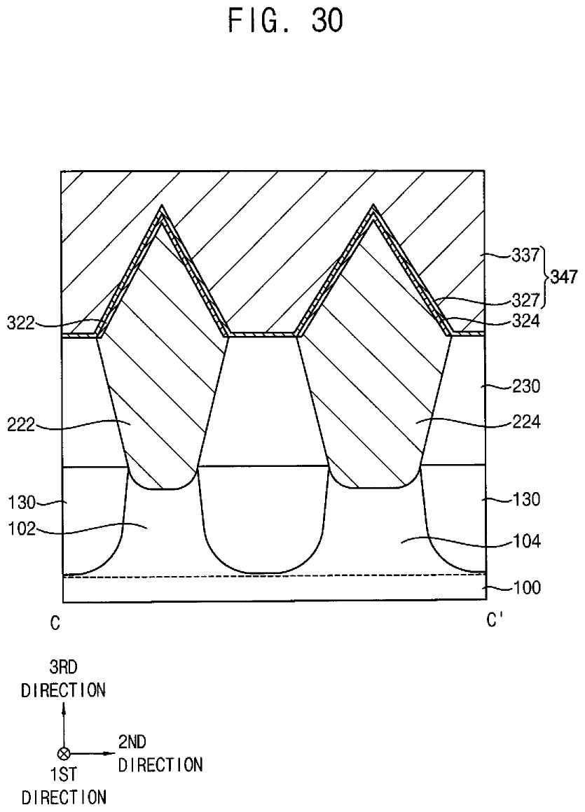

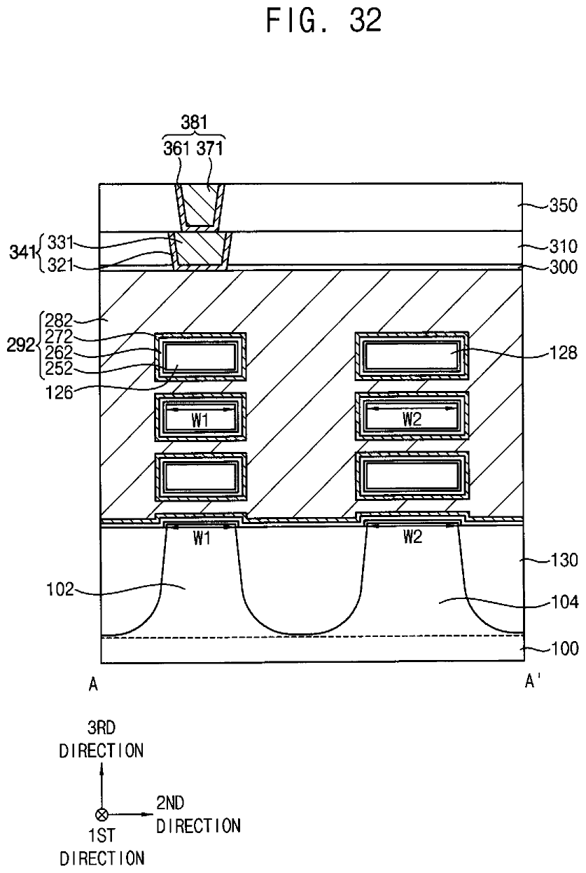

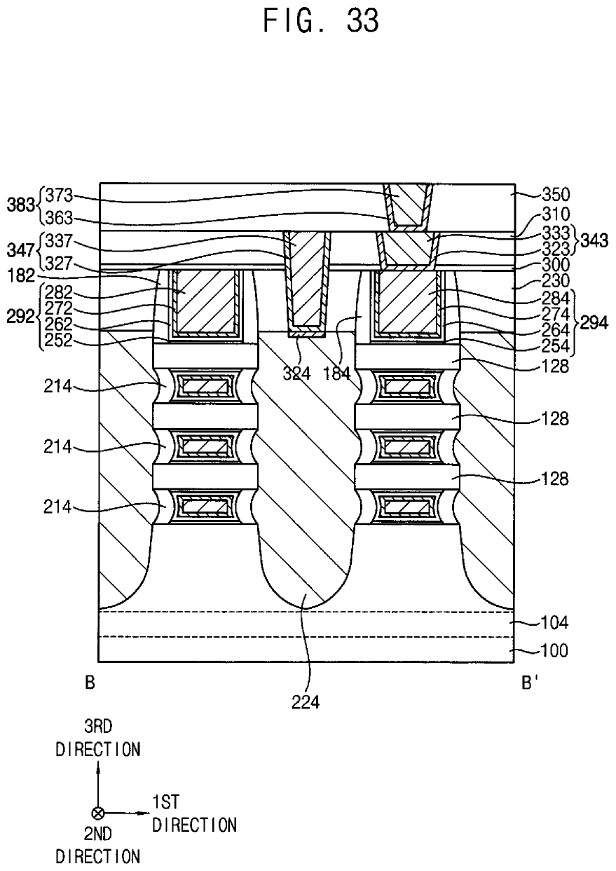

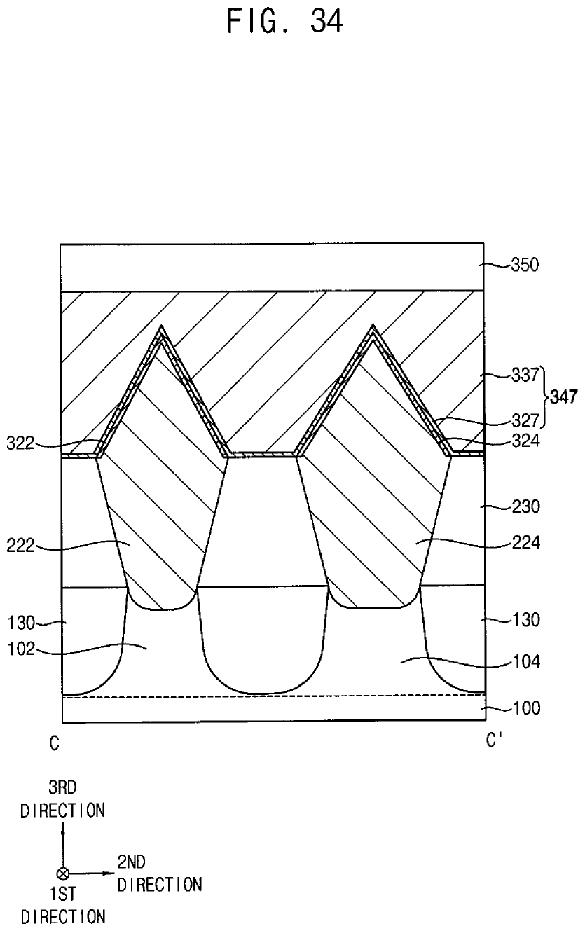

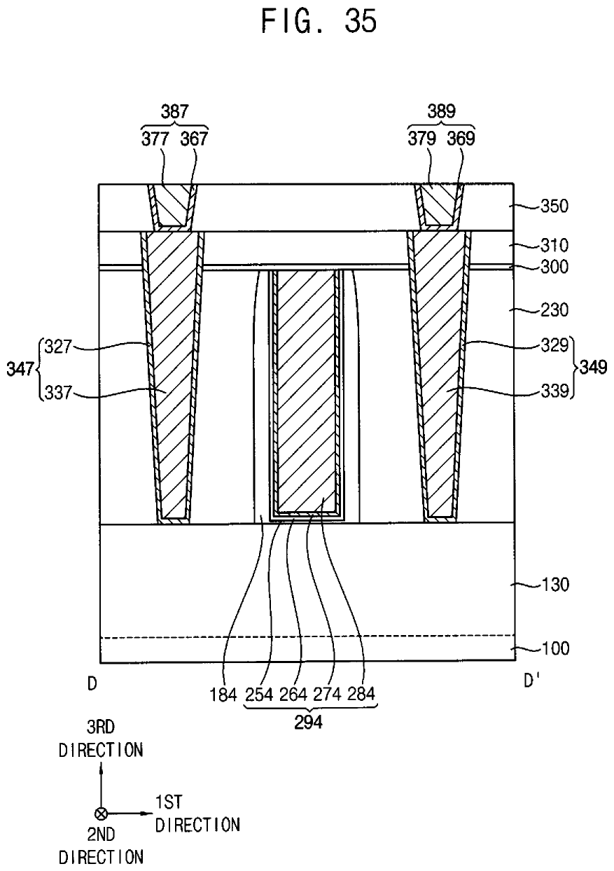

FIGS. 6 to 35 are plan views and cross-sectional views illustrating a method of manufacturing a semiconductor device in accordance with example embodiments. FIGS. 6, 8, 10, 14, 19, 24, 27 and 31 are the plan views, and FIGS. 7, 9, 11-13, 15-18, 20-23, 25, 26, 28-30 and 32-35 are the cross-sectional views. Particularly, FIGS. 7, 9, 11, 15, 25, 28 and 32 are cross-sectional views taken along lines A-A′ of corresponding plan views, respectively, FIGS. 12, 16, 18, 20, 22, 26, 29 and 33 are cross-sectional views taken along lines B-B′ of corresponding plan views, respectively, FIGS. 13, 17, 21, 23, 30 and 34 are cross-sectional views taken along lines C-C′ of corresponding plan views, respectively, and FIG. 35 is a cross-sectional view taken along a line D-D′ of a corresponding plan view.

Referring to FIGS. 6 and 7, a sacrificial layer 110 and a semiconductor layer 120 may be alternately and repeatedly formed on first and second regions I and II of a substrate 100.

In the drawings, the sacrificial layers 110 and the semiconductor layers 120 are formed at three levels, respectively, however, the inventive concept may not be limited thereto.

The semiconductor layer 120 may include substantially the same material as the substrate 100, and the sacrificial layer 110 may include a material having an etching selectivity with respect to the semiconductor layer 120, e.g., silicon-germanium.

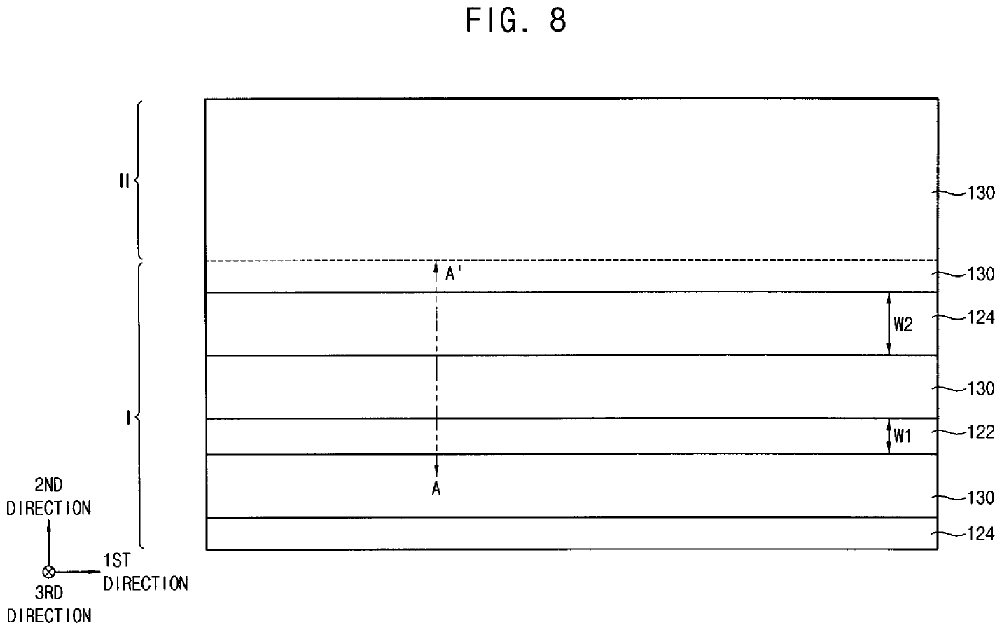

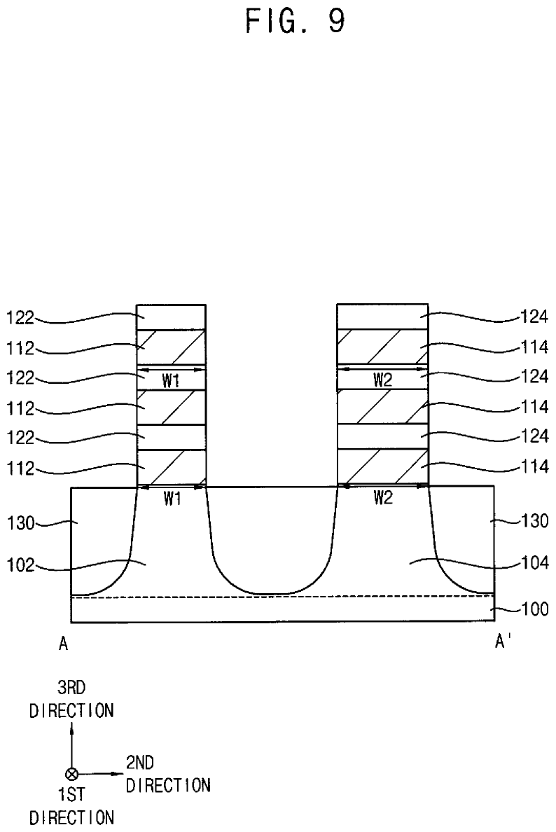

Referring to FIGS. 8 and 9, first and second etching masks may be formed on an uppermost one of the semiconductor layers 120 to extend in the first direction, and the semiconductor layer 120, the sacrificial layer 110 and an upper portion of the substrate 100 may be etched using the first and second etching masks. The first and second etching masks may be formed on the first region I of the substrate 100, and may not be formed on the second region II of the substrate 100.

Thus, first and second active patterns 102 and 104 may be formed on the first region I of the substrate 100 to extend in the first direction, and first and second fin structures may be formed on the first and second active patterns 102 and 104, respectively. The first fin structure may include first sacrificial lines 112 and first semiconductor lines 122 alternately and repeatedly stacked in the third direction, and the second fin structure may include second sacrificial lines 114 and second semiconductor lines 124 alternately and repeatedly stacked in the third direction. The first and second fin structures may be spaced apart from each other in the second direction on the substrate 100.

In example embodiments, a width of the second etching mask in the second direction may be greater than a width of the first etching mask in the second direction, however, the inventive concept may not be limited thereto. That is, the width of the second etching mask in the second direction may be smaller than the width of the first etching mask in the second direction. Hereinafter, only the case in which the width of the second etching mask is greater than that of the first etching mask will be described.

The first and second semiconductor lines 122 and 124 and the first and second sacrificial lines 112 and 114 that may be formed by the etching process using the first and second etching masks may have different widths in the second direction, and upper surfaces of the first and second active patterns 102 and 104 thereunder may also have different widths in the second direction.

In example embodiments, the first semiconductor line 122, the first sacrificial line 112 and the upper surface of the first active pattern 102 may have a first width W1 in the second direction, and the second semiconductor line 124, the second sacrificial line 114 and the upper surface of the second active pattern 104 may have a second width W2 in the second direction that may be greater than the first width W1. Each of the first and second active patterns 102 and 104 may have a width in the second direction gradually decreasing from a top toward a bottom thereof.

In example embodiments, a ratio of the second width W2 with respect to the first width W1 may be equal to or less than about 3.

In example embodiments, the first and second widths W1 and W2 may be equal to or less than about 50 nm.

FIGS. 8 and 9 show only one first active pattern 102 and only one second active pattern 104 on the substrate 100, however, the inventive concept may not be limited thereto. That is, a plurality of first active patterns 102 and a plurality of second active patterns 104 may be formed on the substrate 100.

In example embodiments, a first active pattern structure including a plurality of first active patterns 102 and a second active pattern structure including a plurality of second active patterns 104 may be spaced apart from each other in the second direction. In an example embodiment, the number of the first active patterns 102 included in the first active pattern structure may be different from the number of the second active patterns 104 included in the second active pattern structure.

An isolation pattern 130 may be formed on sidewalls of the first and second active patterns 102 and 104.

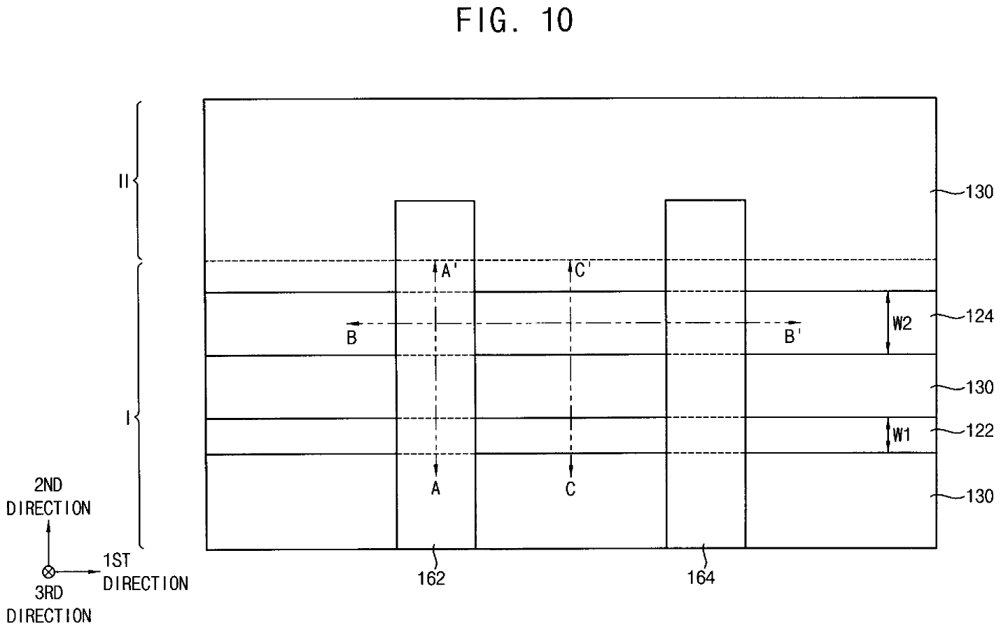

Referring to FIGS. 10 to 13, first and second dummy gate structures 172 and 174 may be formed on the substrate 100 to partially cover the isolation pattern 130 and the first and second fin structures.

Particularly, a dummy gate insulation layer, a dummy gate electrode layer, and a dummy gate mask layer may be sequentially formed on the substrate 100 having the isolation pattern 130 and the first and second fin structures, an etching mask may be formed on the dummy gate mask layer to extend in the second direction, and the dummy gate mask layer may be etched using the etching mask to form first and second dummy gate masks 162 and 164 on the substrate 100.

The dummy gate insulation layer may include an oxide, e.g., silicon oxide, the dummy gate electrode layer may include, e.g., polysilicon, and the dummy gate mask layer may include a nitride, e.g., silicon nitride.

The dummy gate electrode layer and the dummy gate insulation layer may be etched using the first and second dummy gate masks 162 and 164 to form first and second dummy gate electrodes 152 and 154, respectively, and first and second dummy gate insulation patterns 142 and 144, respectively.

The first dummy gate insulation pattern 142, the first dummy gate electrode 152 and the first dummy gate mask 162 sequentially stacked on the first and second active patterns 102 and 104 and a portion of the isolation pattern 130 adjacent thereto may form a first dummy gate structure 172, and the second dummy gate insulation pattern 144, the second dummy gate electrode 154 and the second dummy gate mask 164 sequentially stacked on the first and second active patterns 102 and 104, and a portion of the isolation pattern 130 adjacent thereto may form a second dummy gate structure 174. In example embodiments, each of the first and second dummy gate structures 172 and 174 may extend in the second direction on the first and second fin structures and the isolation pattern 130, and may be formed on upper surfaces and opposite sidewalls in the second direction of the first and second fin structures.

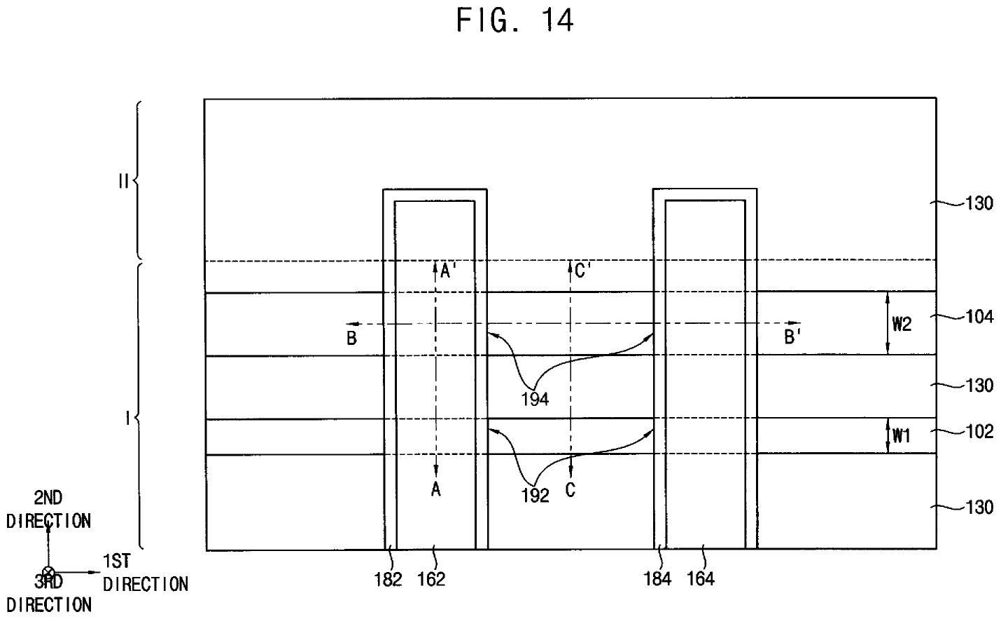

Referring to FIGS. 14 to 17, first and second gate spacers 182 and 184 may be formed on sidewalls of the first and second dummy gate structures 172 and 174, respectively.

Particularly, a spacer layer may be formed on the substrate 100 having the first and second fin structures, the isolation pattern 130, and the first and second dummy gate structures 172 and 174, and may be anisotropically etched to form the first and second gate spacers 182 and 184 on opposite sidewalls in the first direction of the first and second dummy gate structures 172 and 174, respectively.

The first and second fin structures may be etched using the first and second dummy gate structures 172 and 174 and the first and second gate spacers 182 and 184 as an etching mask to form first and second openings 192 and 194 exposing the first and second active patterns 102 and 104, respectively.

Thus, the first and second sacrificial lines 112 and 114 and the first and second semiconductor lines 122 and 124 under the first and second dummy gate structures 172 and 174 and the first and second gate spacers 182 and 184 may be transformed into first and second sacrificial patterns 116 and 118 and first and second semiconductor patterns 126 and 128, respectively, and the first and second fin structures extending in the first direction may be divided into a plurality of first fin structures and a plurality of second fin structures, respectively.

Accordingly, a plurality of first semiconductor patterns 126 may be spaced apart from each other in the first direction, and a plurality of second semiconductor patterns 128 may be spaced apart from each other in the first direction. That is, the first semiconductor patterns 126 may be spaced apart from each other in the first direction on the first active pattern 102 to extend through the first dummy gate structure 172 and the second dummy gate structure 174, respectively, and the second semiconductor patterns 128 may be spaced apart from each other in the first direction on the second active pattern 104 to extend through the first dummy gate structure 172 and the second dummy gate structure 174, respectively.

In example embodiments, the first semiconductor pattern 126 may have a width in the second direction substantially equal to the first width W1 in the second direction of the upper surface of the first active pattern 102, and the second semiconductor pattern 128 may have a width in the second direction substantially equal to the second width W2 in the second direction of the upper surface of the second active pattern 104.

In example embodiments, the first and second semiconductor patterns 126 and 128 may be nano-sheets or nano-wires including a semiconductor material, e.g., silicon, germanium, etc. In example embodiments, each of the first and second semiconductor patterns 126 and 128 may serve as a channel of a transistor, and thus, may be referred to as first and second channels, respectively.

Hereinafter, the first dummy gate structure 172, the first gate spacer 182, and the first fin structure thereunder may be referred to as a first structure, and the second dummy gate structure 174, the second gate spacer 184, and the second fin structure thereunder may be referred to as a second structure. In example embodiments, the first structure may extend in the second direction, and a plurality of first structures may be spaced apart from each other in the first direction. The second structure may extend in the second direction, and a plurality of second structures may be spaced apart from each other in the first direction.

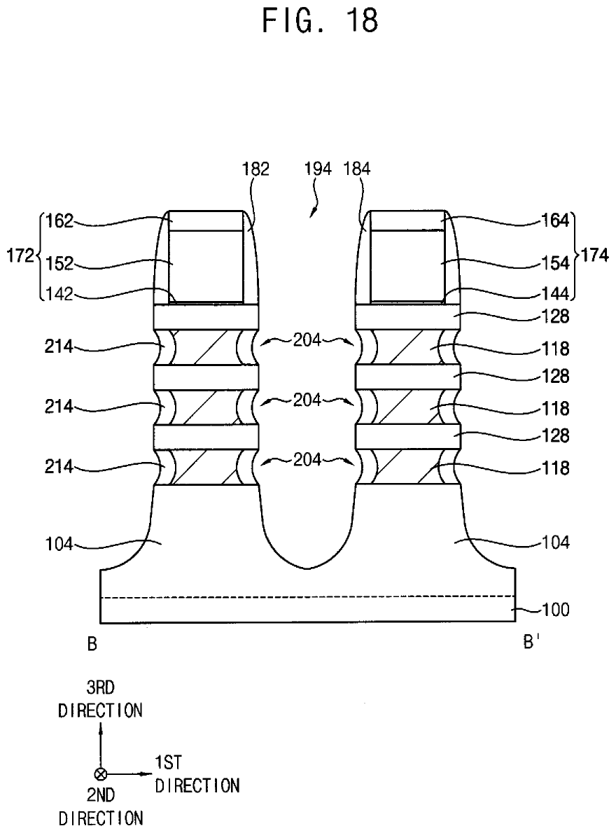

Referring to FIG. 18, opposite lateral portions in the first direction of the first and second sacrificial patterns 116 and 118 exposed by the first and second openings 192 and 194 may be etched to form first recesses and second recesses 204.

In example embodiments, the first recesses and the second recesses 204 may be formed by a wet etching process on the first and second sacrificial patterns 116 and 118. Thus, each of the first recesses and the second recesses 204 may have a concave shape. In example embodiments, each of the first recess and the second recesses 204 may have a cross-section in the first direction having a semi-circular shape. Alternatively, each of the first recess and the second recesses 204 may have a cross-section in the first direction having a rectangular shape with a rounded corner.

In example embodiments, only the first recesses or only the second recesses 204 may be formed. Hereinafter, only the case in which both of the first recesses and the second recesses 204 are formed will be described.

A second spacer layer may be formed on the first and second dummy gate structures 172 and 174, the first and second gate spacers 182 and 184, the first and second fin structures, the first and second active patterns 102 and 104, and the isolation pattern 130 to at least partially fill the first and second openings 192 and 194, and the first recesses and the second recesses 204, and anisotropically etched to form first inner spacers in the first recesses, respectively, and second inner spacers 214 in the second recesses 204, respectively.

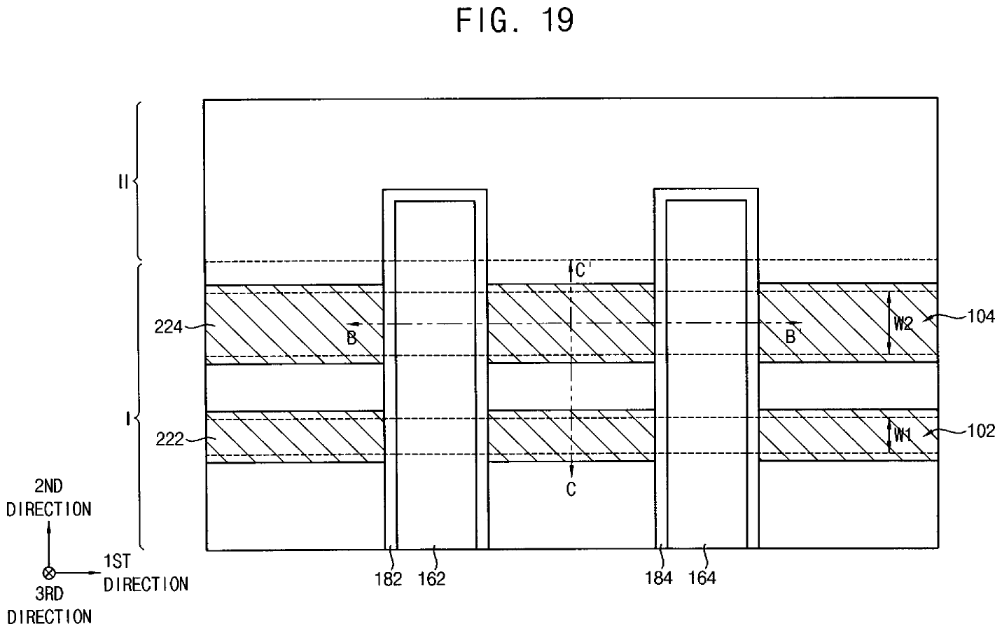

Referring to FIGS. 19 to 21, first and second selective epitaxial growth (SEG) processes may be performed using the first and second active patterns 102 and 104 exposed by the first and second openings 192 and 194, respectively, as seeds to form first and second source/drain layer layers 222 and 224 in the first and second openings 192 and 194, respectively.

In example embodiments, the first SEG process may be performed using a silicon source gas, e.g., disilane (Si₂H₆), a carbon source gas, e.g., SiH₃CH₃, and an n-type impurity source gas, e.g., POCl₃, P₂O₅, etc., so that a single crystalline silicon carbide layer doped with n-type impurities may be formed as the first source/drain layer 222. Alternatively, the first SEG process may be performed using the silicon source gas and the n-type impurity source gas to form a single crystalline silicon layer doped with n-type impurities.

In example embodiments, the second SEG process may be performed using a silicon source gas, e.g., dichlorosilane (SiH₂CL₂), a germanium source gas, e.g., GeH₄, and a p-type impurity source gas so that a single crystalline silicon-germanium layer doped with p-type impurities may be formed as the second source/drain layer 224.

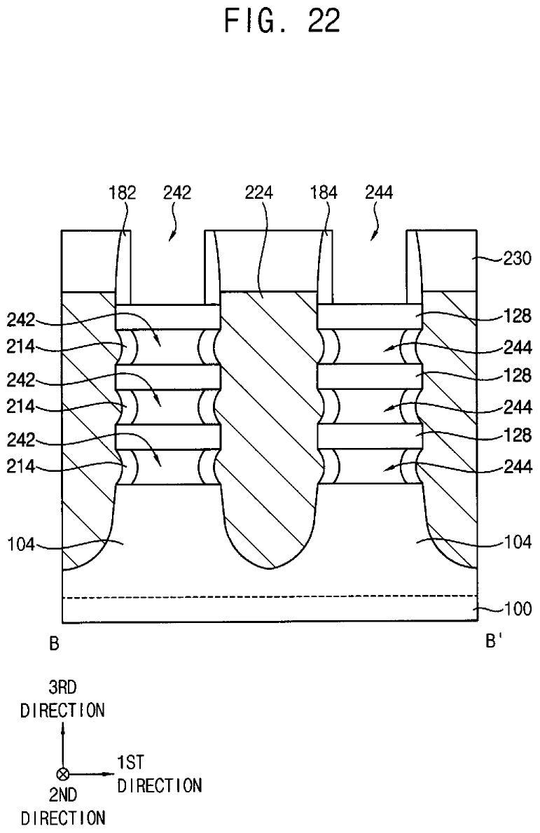

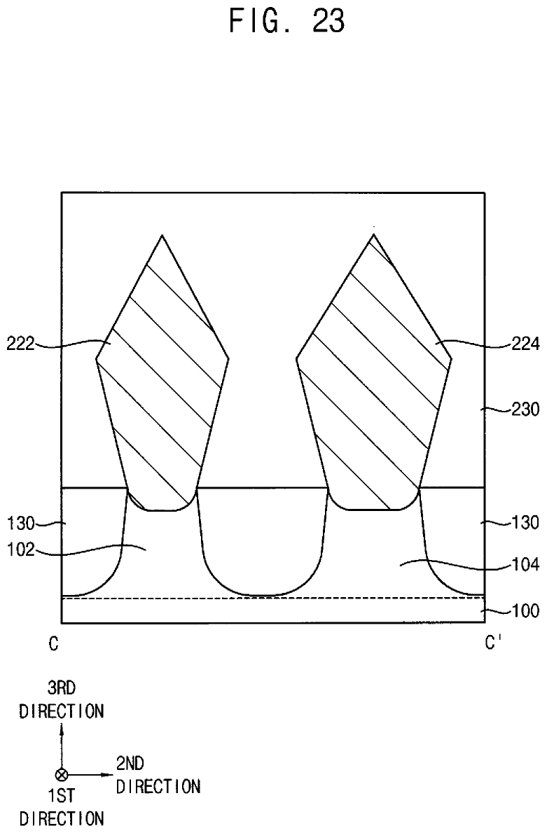

Referring to FIGS. 22 and 23, a first insulating interlayer 230 may be formed on the substrate 100 to cover the first and second structures and the first and second source/drain layers 222 and 224, and may be planarized until upper surfaces of the first and second dummy gate electrodes 152 and 154 of the respective first and second structures are exposed. During the planarization process, the first and second dummy gate masks 162 and 164 may be also removed, and upper portions of the first and second gate spacers 182 and 184 may be removed.

The planarization process may be performed by a chemical mechanical polishing (CMP) process and/or an etch back process.

The exposed first and second dummy gate electrodes 152 and 154, and the first and second dummy gate insulation patterns 142 and 144 thereunder, and the first and second sacrificial patterns 116 and 118 may be removed by, e.g., a wet etching process and/or a dry etching process to form a third opening 242 exposing an inner sidewall of the first gate spacer 182, inner sidewalls of the first inner spacers and the second inner spacers 214, surfaces of the first and second semiconductor patterns 126 and 128, and the upper surfaces of the first and second active patterns 102 and 104, and to form a fourth opening 244 exposing an inner sidewall of the second gate spacer 184, inner sidewalls of the first inner spacers and the second inner spacers 214, surfaces of the first and second semiconductor patterns 126 and 128, and the upper surfaces of the first and second active patterns 102 and 104.

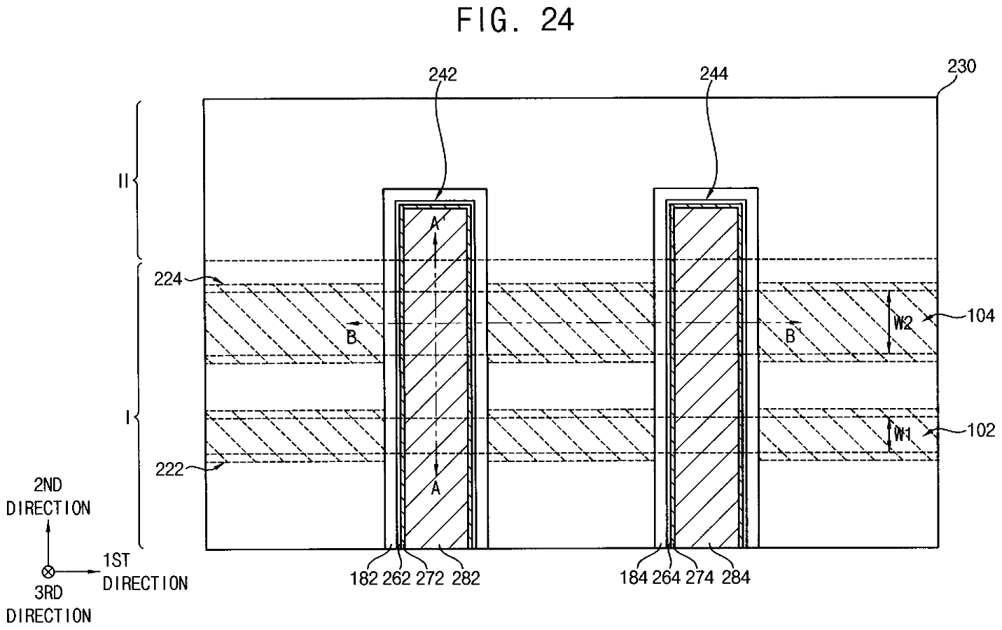

Referring to FIGS. 24 to 26, first and second gate structures 292 and 294 may be formed on the substrate 100 to fill the third and fourth openings 242 and 244, respectively.

Particularly, after a thermal oxidation process is performed on the upper surfaces of the first and second active patterns 102 and 104 and the surfaces of the first and second semiconductor patterns 126 and 128 exposed by the third and fourth openings 242 and 244, respectively, to form first and second interface patterns 252 and 254, respectively, a gate insulation layer and a workfunction control layer may be sequentially formed on surfaces of the first and second interface patterns 252 and 254, the inner sidewalls of the first and second gate spacers 182 and 184, and the first inner spacers and the second inner spacers 214, and an upper surface of the first insulating interlayer 230, and a gate electrode layer may be formed to fill remaining portions of the third and fourth openings 242 and 244.

The gate insulation layer, the workfunction control layer, and the gate electrode layer may be formed by, e.g., a chemical vapor deposition (CVD) process, an atomic layer deposition (ALD) process, a physical vapor deposition (PVD) process, etc. The first and second interface patterns 252 and 254 may be also formed by a CVD process, an ALD process, a PVD process, etc., instead of the thermal oxidation process, and in this case, the first and second interface patterns 252 and 254 may be also formed on the inner sidewalls of the first and second gate spacers 182 and 184, and the first inner spacers and the second inner spacers 214.

The gate electrode layer, the workfunction control layer, and the gate insulation layer may be planarized until the upper surface of the first insulating interlayer 230 is exposed to form first and second gate electrodes 282 and 284, first and second workfunction control patterns 272 and 274, and first and second gate insulation patterns 262 and 264, respectively.

The first interface pattern 252, the first gate insulation pattern 262, the first workfunction control pattern 272, and the first gate electrode 282 may form the first gate structure 292, which may form an NMOS transistor together with the first source/drain layer 222. Additionally, the second interface pattern 254, the second gate insulation pattern 264, the second workfunction control pattern 274, and the second gate electrode 284 may form the second gate structure 294, which may form a PMOS transistor together with the second source/drain layer 224.

A plurality of first semiconductor patterns 126 and a plurality of second semiconductor patterns 128, which may serve as channels, respectively, may be formed in the third direction, and thus, the semiconductor device may be an MBCFET.

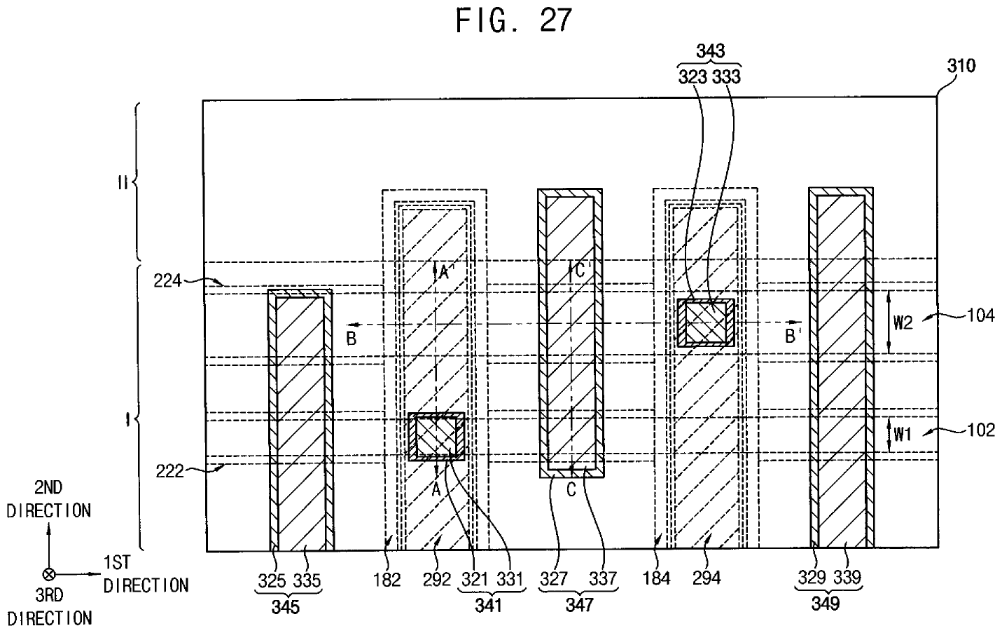

Referring to FIGS. 27 to 30, a capping layer 300 and a second insulating interlayer 310 may be sequentially formed on the first insulating interlayer 230, the first and second gate structures 292 and 294, and the first and second gate spacers 182 and 184. First and second contact plugs 341 and 343 extending through the second insulating interlayer 310 and the capping layer 300 to contact upper surfaces of the first and second gate structures 292 and 294, respectively, and a third contact plug 345 (refer to FIG. 1B) and fourth and fifth contact plugs 347 and 349 extending through the first and second insulating interlayers 230 and 310 and the capping layer 300 to contact upper surfaces of the first and second source/drain layer layers 222 and 224 may be formed.

The first and second contact plugs 341 and 343 may be formed by forming fifth and sixth openings extending through the second insulating interlayer 310 and the capping layer 300 to expose the upper surfaces of the first and second gate structures 292 and 294, respectively, and filling the fifth and sixth openings with a conductive material.

In example embodiments, the fifth and sixth openings may expose the upper surfaces of the first and second gate structures 292 and 294, respectively, that may be formed on the first and second regions I and II of the substrate 100.

The third to fifth contact plugs 345, 347 and 349 may be formed by forming seventh to ninth openings extending through the first and second insulating interlayers 230 and 310, and the capping layer 300 to expose the upper surfaces of the first and second source/drain layers 222 and 224, and filling the seventh to ninth openings with a conductive material.

In example embodiments, the seventh to ninth openings may expose not only upper surfaces of the first and second source/drain layers 222 and 224 on the first region I of the substrate 100 but also an upper surface of a portion of the isolation pattern 130 on the second region II of the substrate 100 adjacent to an end in the second direction of the first region I of the substrate 100. The ninth opening may further expose an upper surface of a portion of the isolation pattern 130 on the second region II of the substrate 100 adjacent to another end in the second direction of the first region I of the substrate 100.

Before forming the third to fifth contact plugs 345, 347 and 349, a metal layer may be formed on the upper surfaces of the first and second source/drain layers 222 and 224 exposed by the seventh to ninth openings, a heat treatment may be performed on the metal layer, and an unreacted portion of the metal layer may be removed to form first and second metal silicide patterns 322 and 324 on the first and second source/drain layers 222 and 224, respectively.

In example embodiments, each of the first to fifth contact plugs 341, 343, 345, 347 and 349 may be formed by forming a barrier layer on bottoms and sidewalls of the fifth to ninth openings and an upper surface of the second insulating interlayer 310, forming a conductive layer on the barrier layer to fill the fifth to ninth openings, and planarizing the conductive layer and the barrier layer until the upper surface of the second insulating interlayer 310 may be exposed. Thus, each of the first to fifth contact plugs 341, 343, 345, 347 and 349 may be formed to form a conductive pattern and a barrier pattern covering a bottom surface and a sidewall thereof.

The first contact plug 341 may include a first barrier pattern 321 and a first conductive pattern 331, the second contact plug 343 may include a second barrier pattern 323 and a second conductive pattern 333, the third contact plug 345 may include a third barrier pattern 325 and a third conductive pattern 335, the fourth contact plug 347 may include a fourth barrier pattern 327 and a fourth conductive pattern 337, and the fifth contact plug 349 may include a fifth barrier pattern 329 and a fifth conductive pattern 339.

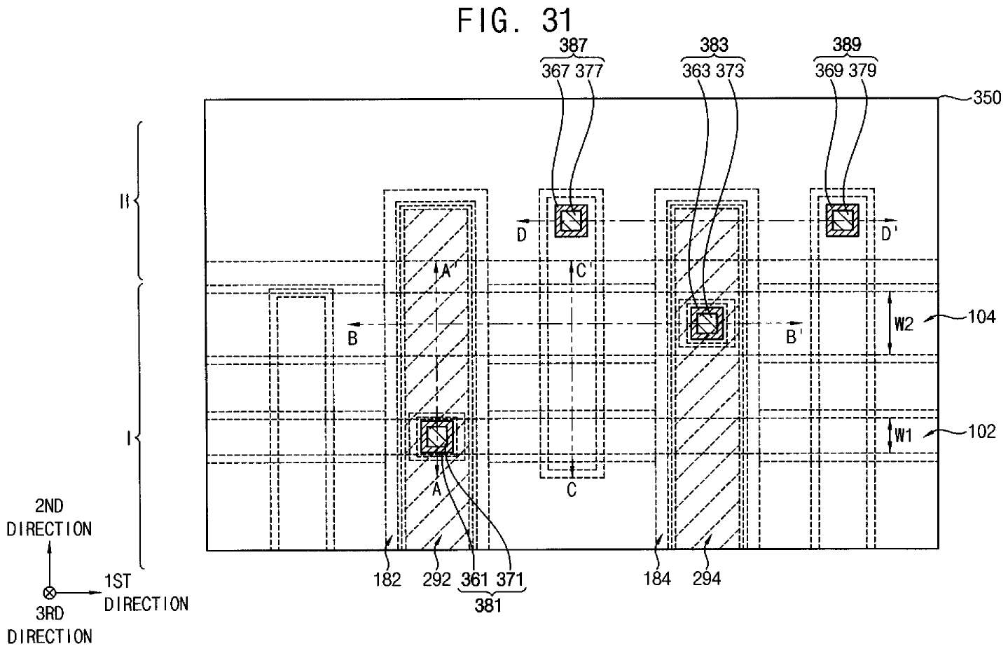

Referring to FIGS. 31 to 35, a third insulating interlayer 350 may be formed on the second insulating interlayer 310 and the first to fifth contact plugs 341, 343, 345, 347 and 349, and first and second vias 381 and 383, a third via 385 (refer to FIG. 1B), and fourth and fifth vias 387 and 389 may be formed through the third insulating interlayer 350 to contact upper surfaces of the first to fifth contact plugs 341, 343, 345, 347 and 349, respectively.

The first and second vias 381 and 383 may be formed on the first region I of the substrate 100, and the third to fifth vias 385, 387 and 389 may be formed on the second region II of the substrate 100.

In example embodiments, the first to fifth vias 381, 383, 385, 387 and 389 may be formed by forming tenth to fourteenth openings extending through the third insulating interlayer 350 to expose upper surfaces of the first to fifth contact plugs 341, 343, 345, 347 and 349, respectively, forming a barrier layer on bottoms and sidewalls of the tenth to fourteenth openings and an upper surface of the third insulating interlayer 350, forming a conductive layer on the barrier layer to fill the tenth to fourteenth openings, and planarizing the conductive layer and the barrier layer until the upper surface of the third insulating interlayer 350 is exposed. Thus, each of the first to fifth vias 381, 383, 385, 387 and 389 may include a conductive pattern and a barrier pattern covering a lower surface and a sidewall of the conductive pattern.

The first via 381 may include a sixth barrier pattern 361 and a sixth conductive pattern 371, the second via 383 may include a seventh barrier pattern 363 and a seventh conductive pattern 373, the third via 385 may include an eighth barrier pattern and an eighth conductive pattern, the fourth via 387 may include a ninth barrier pattern 367 and a ninth conductive pattern 377, and the fifth via 389 may include a tenth barrier pattern 369 and a tenth conductive pattern 379.

Referring to FIGS. 1A, 1B, 1C, 2, 3, 4, and 5 again, a fourth insulating interlayer 390 may be formed on the third insulating interlayer 350 and the first to fifth vias 381, 383, 385, 387 and 389, and a power rail 420 and extending through the fourth insulating interlayer 390 to contact upper surfaces of the third to fifth vias 385, 387 and 389 and wirings (not shown) extending through the fourth insulating interlayer 390 to contact upper surfaces of the first and second vias 381 and 383.

The power rail 420 and the wirings may be formed by forming a fifteenth opening extending through the fourth insulating interlayer 390 to expose the upper surfaces of the third to fifth vias 385, 387 and 389, and sixteenth and seventeenth openings extending through the fourth insulating interlayer 390 to expose the upper surfaces of the first and second vias 381 and 385, respectively, forming a barrier layer on bottoms and sidewalls of the fifteenth to seventeenth openings and an upper surface of the fourth insulating interlayer 390, forming a conductive layer on the barrier layer to fill the fifteenth to seventeenth openings, and planarizing the conductive layer and the barrier layer until the upper surface of the fourth insulating interlayer 390 is exposed. Thus, each of the power rail 420 and the wirings may include a conductive pattern and a barrier pattern covering a lower surface and a sidewall of the conductive pattern.

The power rail 420 may include an eleventh barrier pattern 400 and an eleventh conductive pattern 410, one(s) of the wirings contacting the first via 381 may include a twelfth barrier pattern and a twelfth conductive pattern, and one(s) of the wirings contacting the second via 383 may include a thirteenth barrier pattern and a thirteenth conductive pattern.

In example embodiments, the power rail 420 may extend in the first direction on the second region II of the substrate 100, and each of the wirings may extend in the first direction on the first region I of the substrate 100.

A fifth insulating interlayer (not shown) may be further formed on the fourth insulating interlayer 390, the power rail 420 and the wirings, and upper wirings (not shown) may be further formed to complete the fabrication of the semiconductor device.

As illustrated above, the semiconductor device according to example embodiments may include the first channels 126, which may be spaced apart from each other in the third direction and extend through the first gate structure 292 and the second gate structure 294, and the second channels 128, which may be spaced apart from each other in the third direction and extend through the first gate structure 292 and the second gate structure 294, and thus, may be an MBCFET. The first and second channels 126 and 128 of the NMOS transistor and the PMOS transistor, respectively, may have adjusted widths in the second direction, so as to optimize the performance of the MBCFET.

For example, if an MBCFET having a high performance is needed, the widths of the channels of the NMOS transistor and the PMOS transistor may have a large value. Alternatively, if an MBCFET having a high efficiency is needed, the widths of the channels of the NMOS transistor and the PMOS transistor may have a proper value.

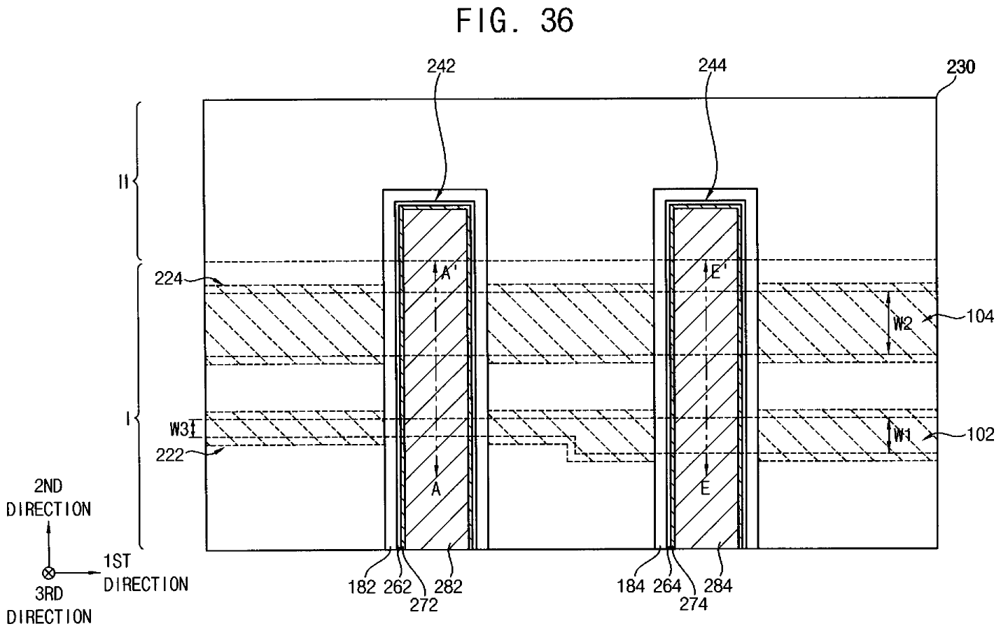

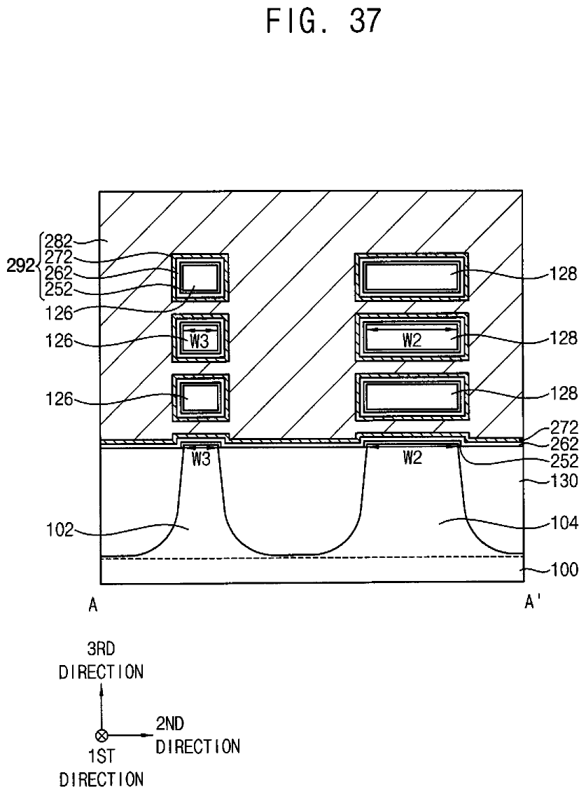

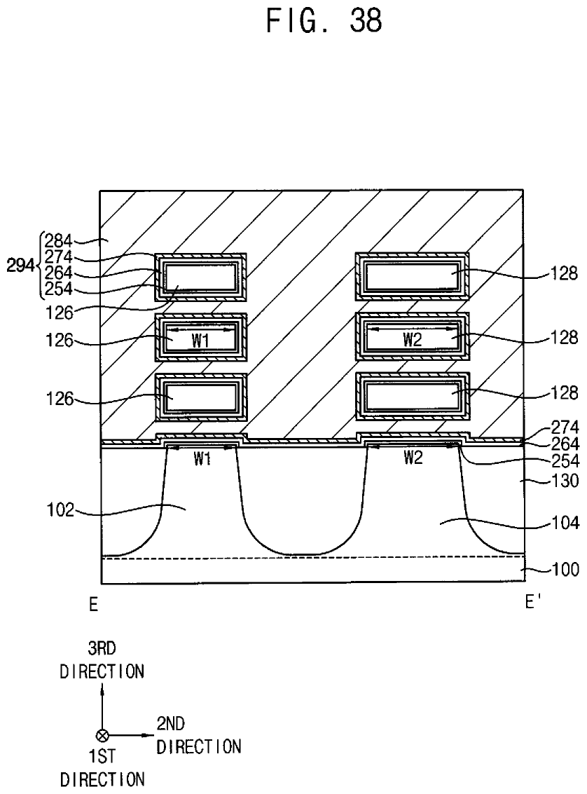

FIGS. 36 to 38 are a plan view and cross-sectional views illustrating a semiconductor device in accordance with example embodiments. FIG. 36 is the plan view, FIG. 37 is a cross-sectional view taken along a line A-A′ of FIG. 36, and FIG. 38 is a cross-sectional view taken along a line E-E′ of FIG. 36.

This semiconductor device may be substantially the same as or similar to that of FIGS. 1 to 5, except for some elements. Thus, like reference numerals refer to like elements, and detailed descriptions thereon are omitted herein. FIG. 36 shows only the active patterns and the gate structures in order to avoid the complexity of the drawing.

Referring to FIGS. 36 to 38, a width in the second direction of the second active pattern 104 may be constant in the first direction, and a width in the second direction of the first active pattern 102 may be variable in the first direction.

A width in the second direction of the first semiconductor pattern 126 extending through the first gate structure 292 in the first direction on the first active pattern 102 may be different from a width in the second direction of the first semiconductor pattern 126 extending through the second gate structure 294 in the first direction on the first active pattern 102.

In example embodiments, a portion of the first active pattern 102 under the second gate structure 294 and the first semiconductor pattern 126 extending through the second gate structure 294 in the first direction on the first active pattern 102 may have the first width W1, portions of the second active pattern 104 under the first and second gate structures 292 and 294, respectively, and second semiconductor patterns 128 extending through the first and second gate structures 292 and 294, respectively, on the second active pattern 104 may have the second width W2, and a portion of the first active pattern 102 under the first gate structure 292 and the first semiconductor pattern 126 extending through the first gate structure 292 in the first direction on the first active pattern 102 may have a third width W3.

In example embodiments, the first to third widths W1, W2 and W3 may be different from each other, for example, the third width W3 may be less than the first width W1, and the first width W1 may be less than the second width W2.

FIG. 36 shows the width of the second semiconductor pattern 128 in the PMOS region is constant in the first direction, and the width of the first semiconductor pattern 126 in the NMOS region is not constant in the first direction, however, the inventive concepts may not be limited thereto. Thus, the width of the second semiconductor pattern 128 in the PMOS region may not be constant in the first direction, and the width of the first semiconductor pattern 126 in the NMOS region may be constant in the first direction.

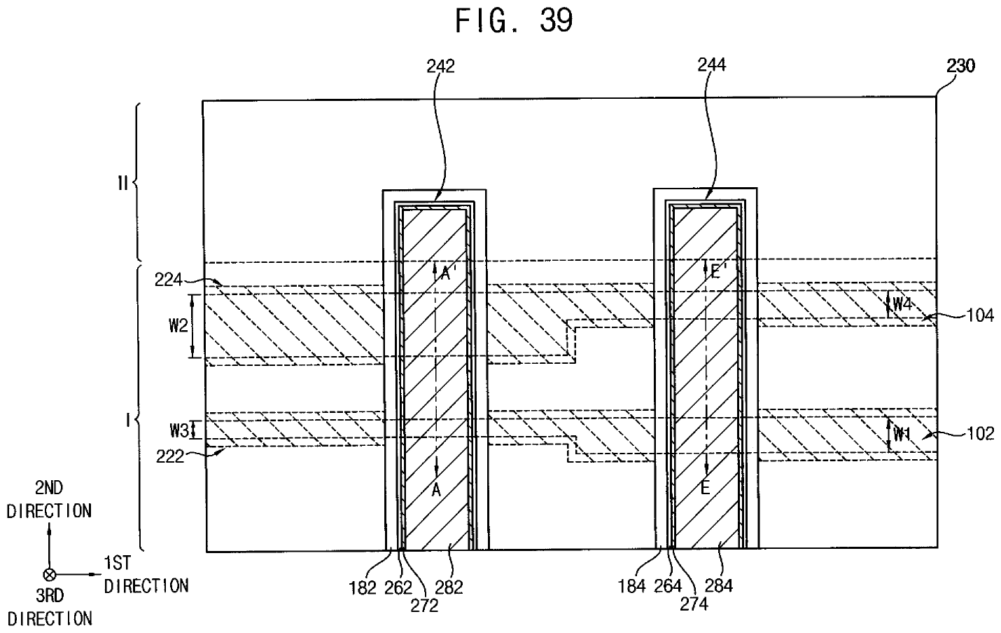

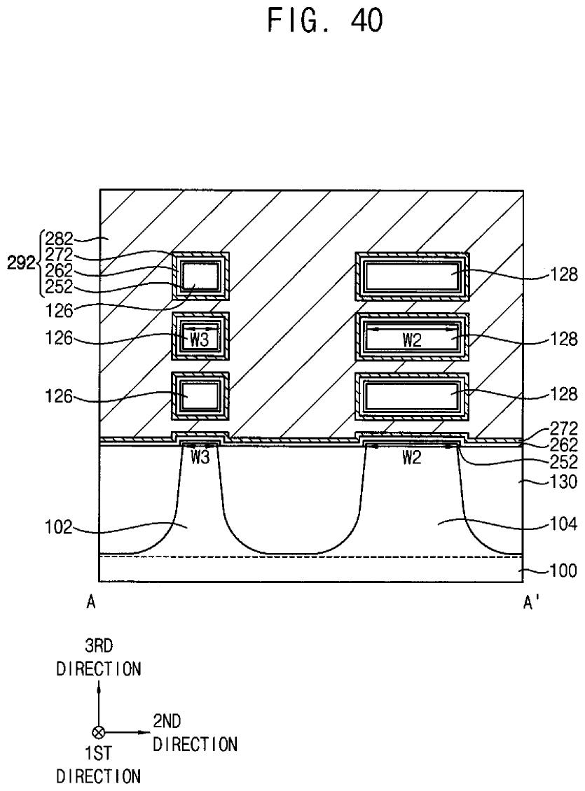

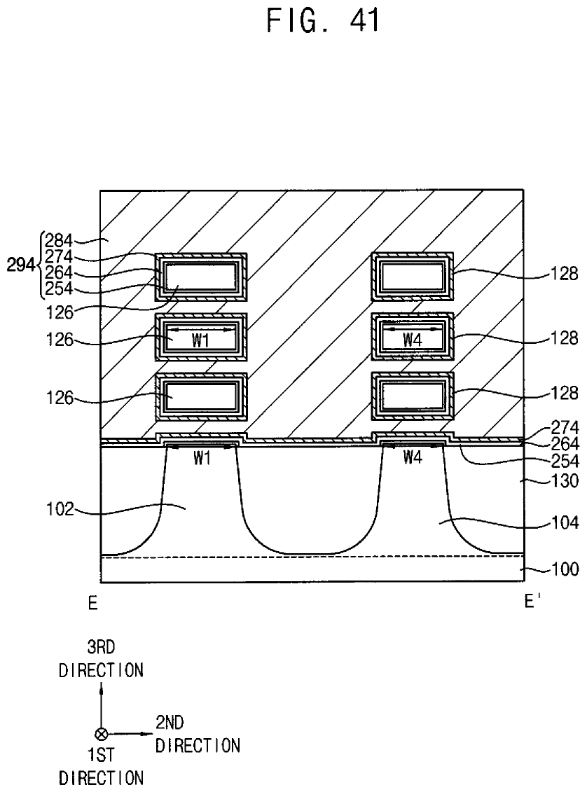

FIGS. 39 to 41 are a plan view and cross-sectional views illustrating a semiconductor device in accordance with example embodiments. FIG. 39 is the plan view, FIG. 40 is a cross-sectional view taken along a line A-A′ of FIG. 39, and FIG. 41 is a cross-sectional view taken along a line E-E′ of FIG. 39.

This semiconductor device may be substantially the same as or similar to that of FIGS. 1 to 5, except for some elements. Thus, like reference numerals refer to like elements, and detailed descriptions thereon are omitted herein. FIG. 39 shows only the active patterns and the gate structures in order to avoid the complexity of the drawing.

Referring to FIGS. 39 to 41, each of the first and second active patterns 102 and 104 may have a width in the second direction that may be variable in the first direction.

A width in the second direction of the first semiconductor pattern 126 extending through the first gate structure 292 in the first direction on the first active pattern 102 may be different from a width in the second direction of the first semiconductor pattern 126 extending through the second gate structure 294 in the first direction on the first active pattern 102, and a width in the second direction of the second semiconductor pattern 128 extending through the first gate structure 292 in the first direction on the second active pattern 104 may be different from a width in the second direction of the second semiconductor pattern 128 extending through the second gate structure 294 in the first direction on the second active pattern 104.

In example embodiments, a portion of the first active pattern 102 under the second gate structure 294 and the first semiconductor pattern 126 extending through the second gate structure 294 in the first direction on the first active pattern 102 may have the first width W1, a portion of the second active pattern 104 under the first gate structure 292 and the second semiconductor pattern 128 extending through the first gate structure 292 in the first direction on the second active pattern 104 may have the second width W2, a portion of the first active pattern 102 under the first gate structure 292 and the first semiconductor pattern 126 extending through the first gate structure 292 in the first direction on the first active pattern 102 may have the third width W3, and a portion of the second active pattern 104 under the second gate structure 294 and the second semiconductor pattern 128 extending through the second gate structure 294 in the first direction on the second active pattern 104 may have a fourth width W4.

In example embodiments, the first to fourth widths W1, W2, W3 and W4 may be different from each other, for example, the second width W2 may be greater than the first width W1, the first width W1 may be greater than the fourth width W4, and the fourth width W4 may be greater than the third width W3.

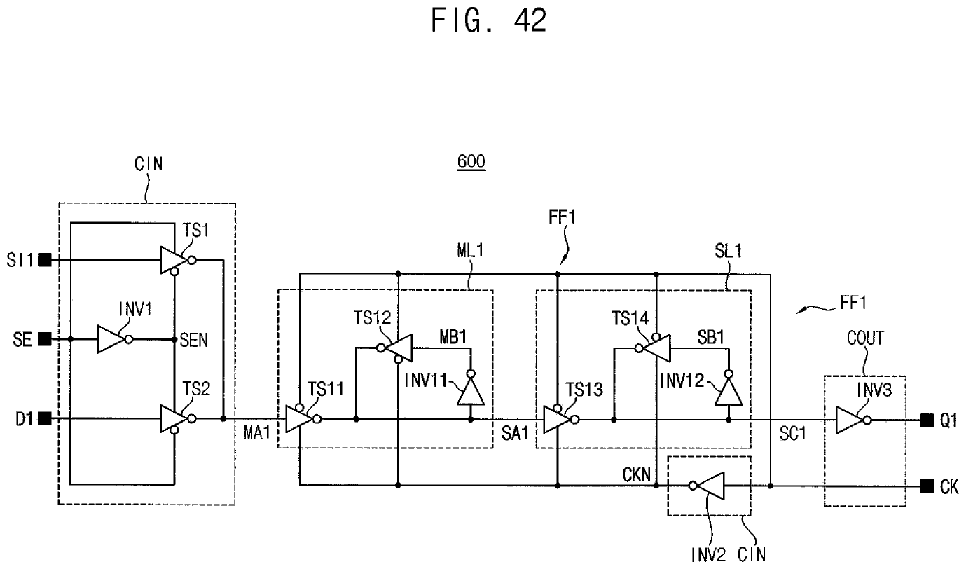

FIG. 42 is a circuit diagram illustrating a one-bit flip-flop in accordance with example embodiments. An integrated circuit 600 shown in FIG. 42 is an example of a master-slave type one-bit flip-flop.

Referring to FIG. 42, the integrated circuit 600 may include a first flip-flop FF1, and may further include an input circuit CIN and an output circuit COUT.

The first flip-flop FF1 may include a first master latch ML1 and a first slave latch SL1. The first master latch ML1 may be synchronized with a clock signal CK and an inverted clock signal CKN, and latch a first input signal MA1 to generate a first master output signal SA1, and the first slave latch SL1 may be synchronized with the clock signal CK and the inverted clock signal CKN, and latch the first master output signal SA1 to generate a first slave output signal SC1.

The first master latch ML1 may include a first tri-state inverter TS11, a second tri-state inverter TS12 and an inverter INV11, the first slave latch SL1 may include a third tri-state inverter TS13, a fourth tri-state inverter TS14 and an inverter INV12.

The tri-state inverters TS11, TS12, TS13 and TS14 may be synchronized with the clock signal CK and the inverted clock signal CKN to be operated. The first tri-state inverter TS11 may have a node of the first input signal MA1 as an input, and a node of the first master output signal SA1 as an output. The second tri-state inverter TS12 may have a node of a first inverted master output signal MB1, which may be inverted from the first master output signal SA1, as an input, and a node of the first master output signal SA1 as an output. The third tri-state inverter TS13 may have a node of the first master output signal SA1 as an input, and a node of the first slave output signal SC1 as an output. The fourth tri-state inverter TS14 may have a node of a first inverted slave output signal SB1, which may be inverted from the first slave output signal SC1, as an input, and a node of the first slave output signal SC1 as an output.

The input circuit CIN may include inverters INV1 and INV2 and tri-state inverters TS1 and TS2. The input circuit CIN may provide one of a first scan input signal SI1 and a first data signal D1 as the first input signal MA1 in response to a scan enable signal SE and an inverted scan enable signal SEN. Additionally, the input signal CIN may provide the clock signal CK and the inverted clock signal CKN. The output circuit COUT may include an inverter INV3 that may buffer the first slave output signal SC1 to provide a final output signal Q1.

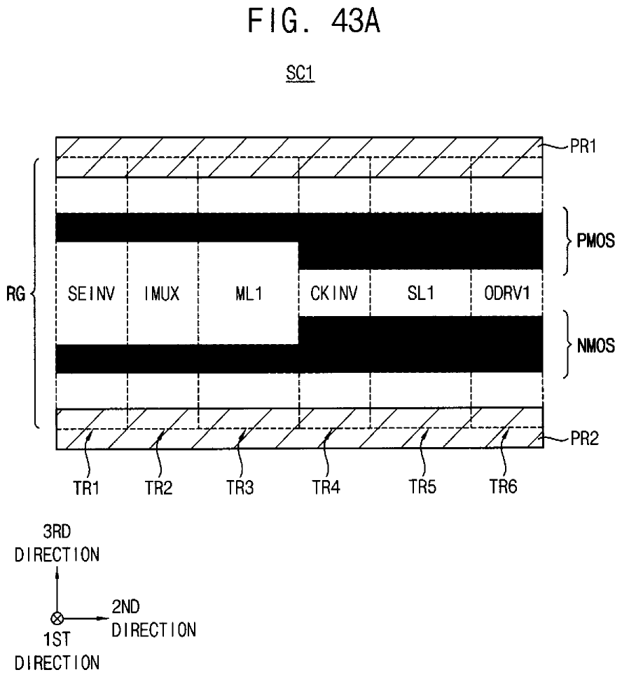

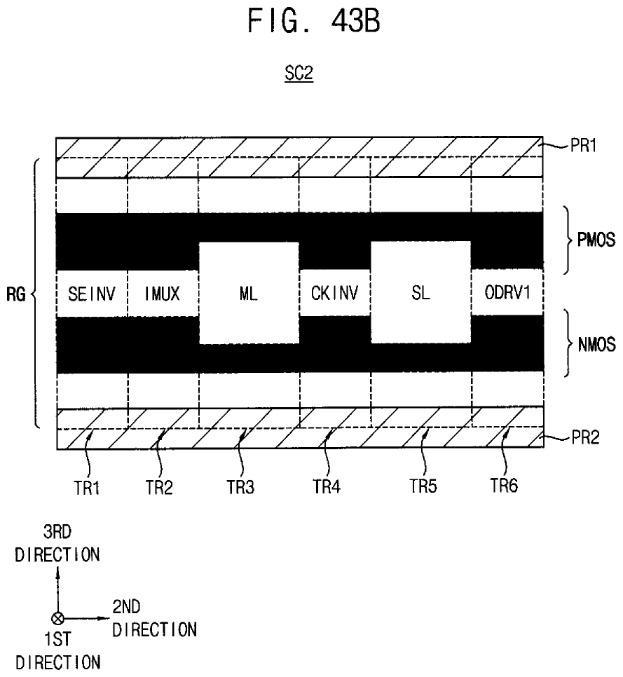

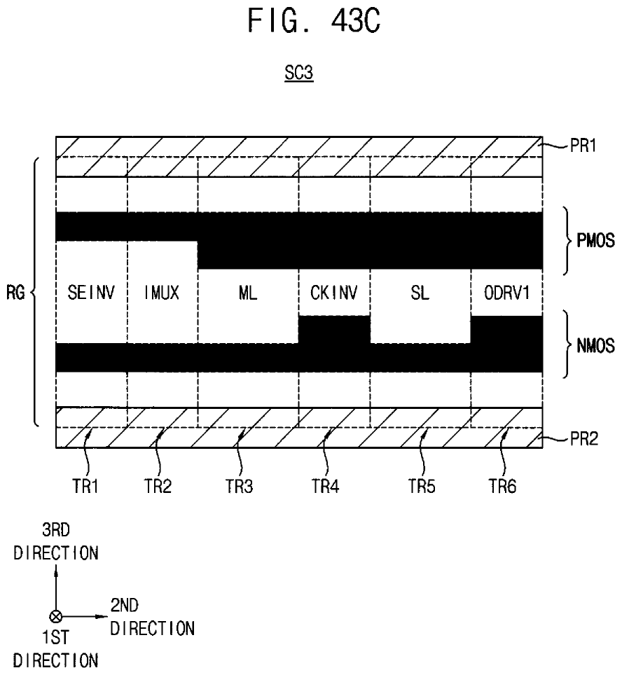

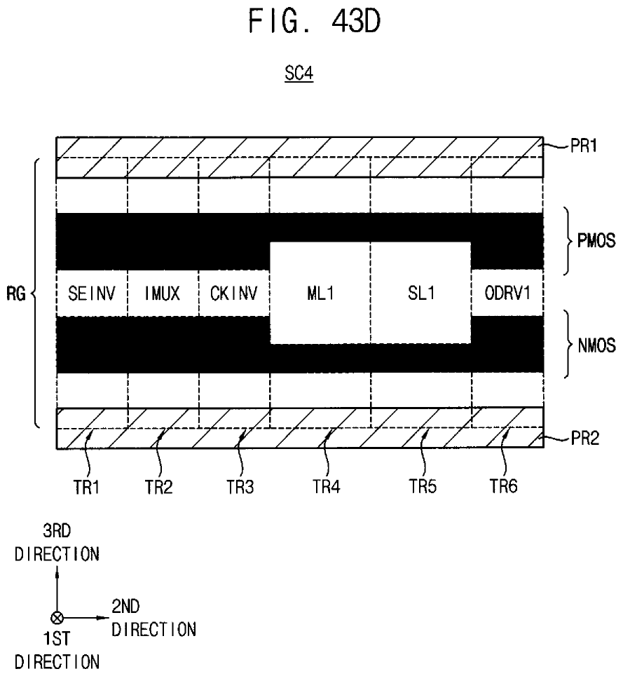

FIGS. 43A to 43D illustrate layouts of standard cells corresponding to the one-bit flip-flop of FIG. 42 in accordance with example embodiments.

In FIGS. 43A to 43D, a scan enable inverter SEINV may correspond to the inverter INV1 of FIG. 42, an input multi-flexer IMUX may correspond to the tri-state inverters TS1 and TS2 of FIG. 42, a master latch ML1 may correspond to the first master latch ML1 of FIG. 42, a slave latch SL1 may correspond to the first slave latch SL1 of FIG. 42, an output driver ODRV1 may correspond to the inverter INV3 of FIG. 42, and a clock inverter CKINV may correspond to the inverter INV2 of FIG. 42.

A first power rail PR1 at a side of a row region RG may include high power rails for providing a first source voltage VDD, a second power rail PR1 at another side of the row region RG may include low power rails for providing a second source voltage VSS less than the first source voltage VDD. In example embodiments, the first source voltage VDD may be a positive voltage, and the second source voltage VSS may be a ground voltage, that is, a zero voltage, or a negative voltage.

Referring to FIG. 43A, a first standard cell SC1 may include the first power rail PR1, the second power rail PR2, and first to sixth transistor regions TR1, TR2, TR3, TR4, TR5 and TR6 arranged in the second direction, which may divide the row region RG between the first and second power rails PR1 and PR2.

First to sixth transistors may be formed in the first to sixth transistor regions TR1, TR2, TR3, TR4, TR5 and TR6, respectively, and may include first to sixth channels, respectively. In example embodiments, ones of the first to sixth channels close to the first power rail PR1 may serve as channels of a PMOS transistor, and ones of the first to sixth channels close to the second power rail PR2 may serve as channels of an NMOS transistor. Alternatively, ones of the first to sixth channels close to the first power rail PR1 may serve as channels of the NMOS transistor, and ones of the first to sixth channels close to the second power rail PR2 may serve as channels of the PMOS transistor.

The first transistor may form the scan enable inverter SEINV, the second transistor may form the input multi-flexer IMUX, the third transistor may form the first master latch ML1. The fourth transistor may form the clock inverter CKINV, the fifth transistor may form the first slave latch SL1, and the sixth transistor may form the output driver ODRV1.

In example embodiments, the first to third channels having relatively small widths may be formed in the first to third transistor regions TR1, TR2 and TR3, respectively, and the fourth to sixth channels having relatively large widths may be formed in the fourth to sixth transistor regions TR4, TR5 and TR6, respectively. Thus, the layout of the first standard cell SC1 may be designed such that transistors having a high efficiency may be formed in the first to third transistor regions TR1, TR2 and TR3, and transistors having a high performance may be formed in the fourth to sixth transistor regions TR4, TR5 and TR6. In an example embodiment, the layout of the first standard cell SC1 may be designed such that at least the clock inverter CKINV and the output driver ODRV1 included in the first flip-flop FF1 may be formed in the high performance transistor region.

A second standard cell SC2 of FIG. 43B may be substantially the same as or similar to that of the first standard cell SC1 of FIG. 43A, except that the first and second channels having relatively large widths are formed in the first and second transistor regions TR1 and TR2, respectively, and the third and fifth channels having relatively small widths are formed in the third and fifth transistor region TR3 and TR5.

Thus, the layout of the second standard cell SC2 may be designed such that at least the master latch ML1 and the slave latch SL1 included in the first flip-flop FF1 may be formed in the high efficiency transistor region.

A third standard cell SC3 of FIG. 43C may be substantially the same as or similar to that of the first standard cell SC1 of FIG. 43A, except that the third channels included in the PMOS transistor of the third transistors in the third transistor TR3 have relatively large widths, and the fifth channels included in the NMOS transistor of the fifth transistors in the fifth transistor TR5 have relatively small widths.

Thus, the layout of the third standard cell SC3 may be designed such that the scan enable inverter SEINV and the input multi-flexer IMUX included in the first flip-flop FF1 may be formed in the high efficiency transistor region, the master latch ML1 and the slave latch SL1 may be formed in a middle performance transistor regions, and the clock inverter CKINV and the output driver ODRV1 may be formed in the high performance transistor region.

A fourth standard cell SC4 of FIG. 43D may be substantially the same as or similar to that of the first standard cell SC1 of FIG. 43A, except that the clock inverter CKINV is formed in the third transistor region TR3, and the master latch ML1 is formed on the fourth transistor region TR4.

Thus, the layout of the fourth standard cell SC4 may be designed such that the master latch ML1 and the slave latch SL1 may be formed to be close to each other in the same performance transistor region, so as to increase the efficiency of designing.

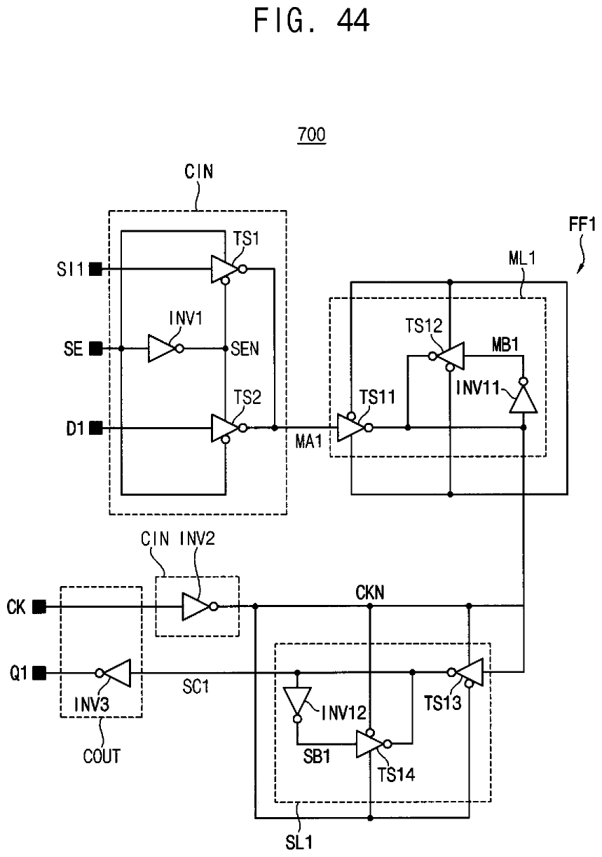

FIG. 44 is a circuit diagram illustrating a multi-bit flip-flop in accordance with example embodiments. FIG. 44 illustrates an integrated circuit 700 of a master-slave type two-bit flip-flop.

The integrated circuit 700 may include a first flip-flop FF1 having a modified structure, and may further include an input circuit CIN and an output circuit COUT. The first flip-flop FF1 of FIG. 44 having the modified structure may be substantially the same as or similar to the first flip-flop of FIG. 42, and thus, repeated descriptions thereon are omitted herein.

Referring to FIG. 44, the integrated circuit 700 may include the first master latch ML1 and the first slave latch SL1 arranged in different rows.

The input circuit CIN including the inverter INV1 and the tri-state inverter TS1 and the first master latch ML1 may be arranged in the same row, and the input circuit CIN including the inverter INV2 and the tri-state inverter TS2 and the first slave latch SL1 may be arranged in the same row. The output circuit COUT may be arranged in the same row as the first slave latch SL1.

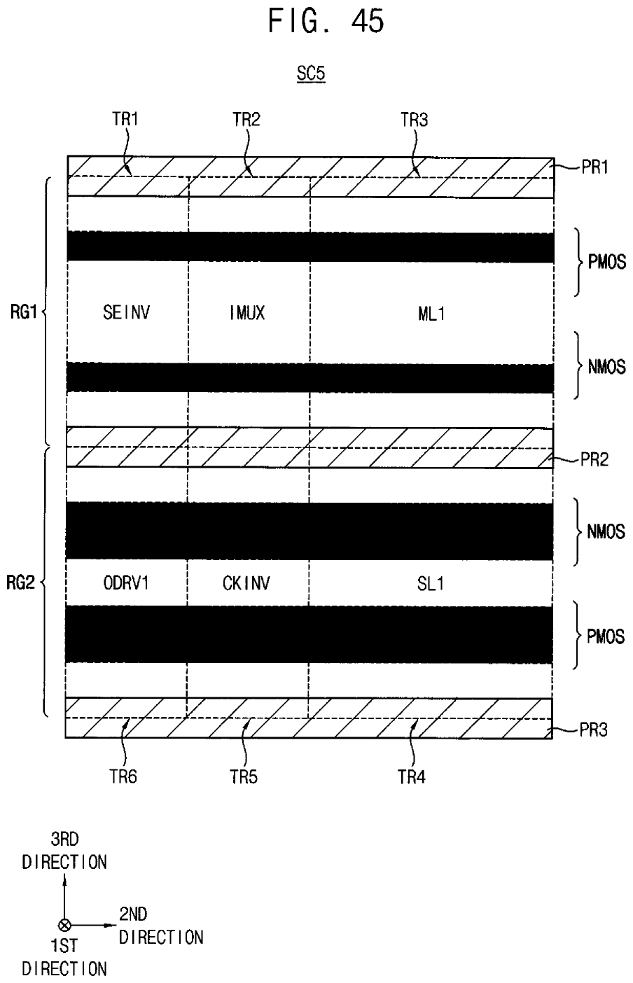

FIG. 45 illustrates a layout of a standard cell corresponding to the two-bit flip-flop of FIG. 44.

A fifth standard cell SC5 may be substantially the same as or similar to those of the first to fourth standard cells SC1, SC2, SC3 and SC4, except that the scan enable inverter SEINV, the input multi-flexer IMUX and the master latch ML1 are arranged in a first row region RG1 and the slave latch SL1, the clock inverter CKINV and the output driver ODRV1 are arranged in a second row region RG2, and thus, repeated descriptions thereon are omitted herein.

In example embodiments, a first power rail PR1 at a side of the first row region RG1 may include high power rails for providing a first source voltage VDD, a third power rail PR3 at a side of the second row region RG2 may include high power rails for providing a third source voltage substantially equal to the first source voltage VDD, and a second power rail PR2 at a boundary between the first and second row regions RG1 and RG2 may include low power rails for providing a second source voltage VSS less than the first and third source voltages VDD. The first and third source voltages VDD may be a positive voltage, and the second source voltage VSS may be a ground voltage, that is, a zero voltage, or a negative voltage.

Alternatively, the first and third power rails PR1 and PR3 at a side of the first row region RG1 and at a side of the second row region RG2, respectively, may include low power rails for providing first and third source voltages VSS, and the second power rail PR2 at a boundary between the first and second row regions RG1 and RG2 may include high power rails for providing a second source voltage VDD greater than the first and third source voltages VSS. The second source voltage VDD may be a positive voltage, and the first and third source voltage VSS may be a ground voltage, that is, a zero voltage, or a negative voltage.

Referring to FIG. 45, the fifth standard cell SC5 may include the first to third power rails PR1, PR2 and PR3 spaced apart from each other in the third direction, and may further include first to third transistor regions TR1, TR2 and TR3 arranged in the second direction to divide the first row region RG1 between the first and second power rails PR1 and PR2, and fourth to sixth transistor regions TR4, TR5 and TR6 arranged in the second direction to divide the second row region RG2 between the second and third power rails PR2 and PR3.

One(s) of the first to third channels in the first to third transistor regions TR1, TR2 and TR3, respectively, that may be close to the first power rail PR1 may serve as a channel of a PMOS transistor, and other one(s) thereof that may be close to the second power rail PR2 may serve as a channel of an NMOS transistor. One(s) of the fourth to sixth channels in the fourth to sixth transistor regions TR4, TR5 and TR6, respectively, that may be close to the second power rail PR2 may serve as a channel of an NMOS transistor, and other one(s) thereof that may be close to the third power rail PR3 may serve as a channel of a PMOS transistor.

In example embodiments, the first to third channels in the first row region RG1 may have relatively small widths, and the fourth to sixth channels in the second row region RG2 may have relatively large widths.

Thus, the layout of the fifth standard cell SC5 may be designed such that at least the master latch ML1 included in the first flip-flop FF1 may be formed in the high efficiency transistor region. Additionally, the first to third channels having relatively small widths and the fourth to sixth channels having relatively large widths may be formed in respective row regions, so that the layout of the fifth standard cell SC5 may be efficiently designed.

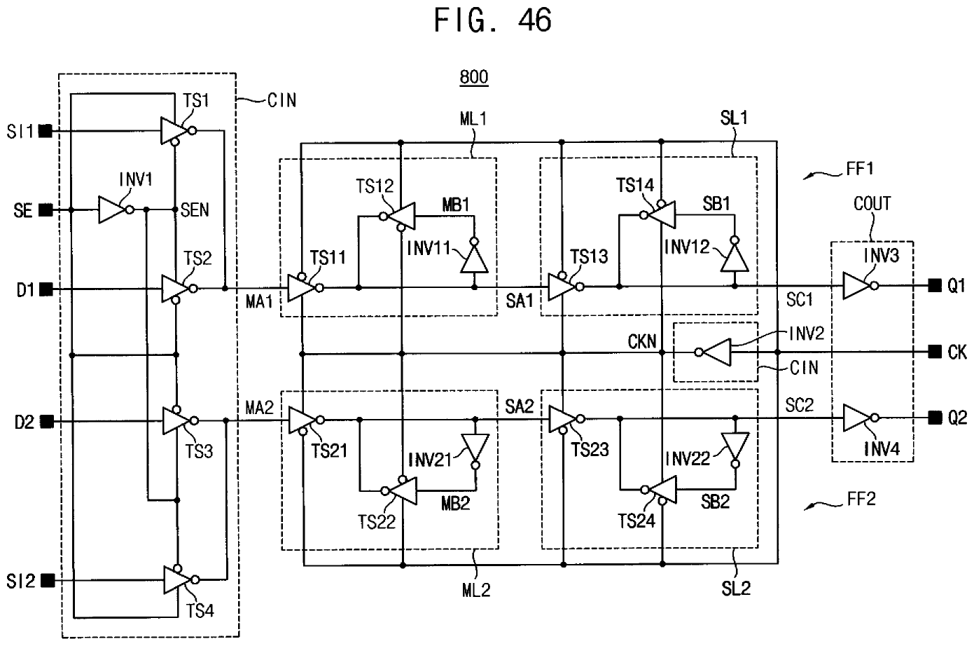

FIG. 46 is a circuit diagram illustrating a multi-bit flip-flop in accordance with example embodiments. FIG. 46 illustrates an integrated circuit 800 of a master-slave type two-bit flip-flop.

Referring to FIG. 46, the integrated circuit 800 may include a first flip-flop FF1 and a second flip-flop FF2, and may further include an input circuit CIN and an output circuit COUT. The first flip-flop FF1 of FIG. 46 may have a structure substantially the same as or similar to that of the first flip-flop FF1 of FIG. 42, and thus, repeated descriptions thereon are omitted herein.

The second flip-flop FF2 may include a second master latch ML2 and a second slave latch SL2. The second master latch ML2 may be synchronized with a clock signal CK and an inverted clock signal CKN, and may latch a second input signal MA2 to generate a second master output signal SA2, and the second slave latch SL2 may be synchronized with the clock signal CK and the inverted clock signal CKN, and may latch the second master output signal SA2 to generate a second slave output signal SC2.

The second master latch ML2 may include a fifth tri-state inverter TS21, a sixth tri-state inverter TS22 and an inverter INV21, and the second slaver latch SL2 may include a seventh tri-state inverter TS23, an eighth tri-state inverter TS24 and an inverter INV22. The tri-state inverters TS21, TS22, TS23 and TS24 may be synchronized with the clock signal CK and the inverted clock signal CKN to be operated. The fifth tri-state inverter TS21 may have a node of the second input signal MA2 as an input, and may have a node of the second master output signal SA2 as an output. The sixth tri-state inverter TS22 may have a node of a second inverted master output signal MB2, which may be inverted from the second master output signal SA2, as an input, and may have a node of the second master output signal SA2 as an output. The seventh tri-state inverter TS23 may have a node of the second master output SA2 as an input, and may have a node of the second slave output signal SC2 as an output. The eighth tri-state inverter TS24 may have a node of a second inverted slave output signal SB2, which may be inverted from the second slave output signal SC2, as an input, and may have a node of the second slave output signal SC2 as an output.

The input circuit CIN may include inverters INV1 and INV2 and tri-state inverters TS1, TS2, TS3 and TS4. The input circuit CIN may provide one of a first scan input signal SI1 and a first data signal D1 as a first input signal MA1 in response to a scan enable signal SE and an inverted scan enable signal SEN, and may provide one of a second scan input signal SI2 and a second data signal D2 as a second input signal MA2. Additionally, the input circuit CIN may provide the clock signal CK and the inverted signal CKN. The output circuit COUT may include inverters INV3 and INV4 that may buffer the first slave output signal SC1 and the second slave output signal SC2 to provide final output signals Q1 and Q2.

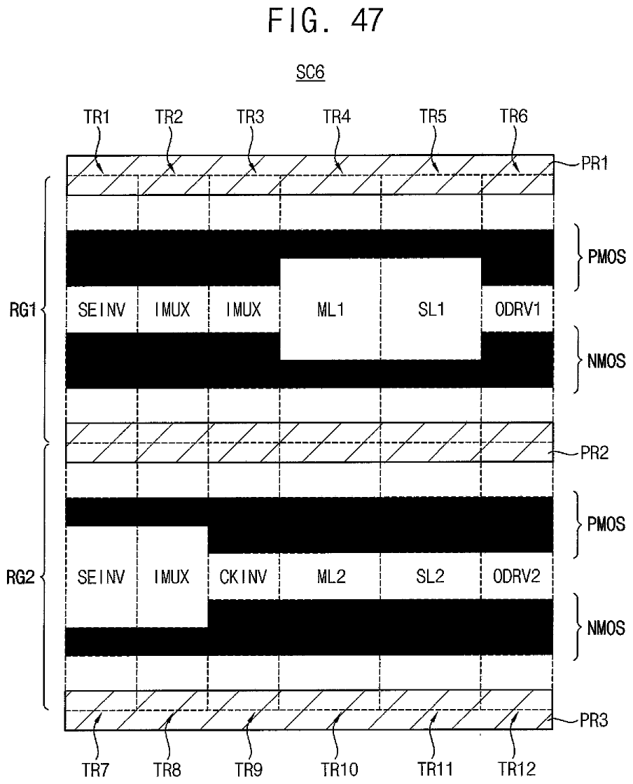

FIG. 47 illustrates a layout of a standard cell corresponding to the two-bit flip-flop of FIG. 46.

A scan enable inverter SEINV may correspond to the inverter INV1 of FIG. 46, an input multi-flexer IMUXs may correspond to the tri-state inverters TS1, TS2, TS3 and TS4 of FIG. 46, a first master latch ML1, a second master latch ML2, a first slave latch SL1 and a second slave latch SL2 may correspond to the latches ML1, ML2, SL1 and SL2, respectively, first and second output drivers ODRV1 and ODRV2 may correspond to the inverters INV3 and INV4 of FIG. 46, and a clock inverter CKINV may correspond to the inverter INV2 of FIG. 46. A sixth standard cell SC6 of FIG. 47 may be substantially the same as or similar to the first to fourth standard cells SC1, SC2, SC3 and SC4 of FIGS. 43A to 43D, respectively, and thus, repeated descriptions thereon are omitted herein.

Referring to FIG. 47, the sixth standard cell SC6 may include first to third power rails PR1, PR2 and PR3 spaced apart from each other in the third direction, and may further include first to sixth transistor regions TR1, TR2, TR3, TR4, TR5 and TR6 arranged in the second direction to divide a first row region RG1 between the first and second power rails PR1 and PR2, and seventh to twelfth transistor regions TR7, TR8, TR9, TR10, TR11 and TR12 arranged in the second direction to divide a second row region RG2 between the second and third power rails PR2 and PR3.

One(s) of first to sixth channels in the first to sixth transistor regions TR1, TR2, TR3, TR4, TR5 and TR6, respectively, that may be close to the first power rail PR1 may serve as channels of a PMOS transistor, and other one(s) thereof that may be close to the second power rail PR2 may serve as channels of an NMOS transistor. Seventh to twelfth channels in the seventh to twelfth transistor regions TR7, TR8, TR9, TR10, TR11 and TR12, respectively, that may be close to the second power rail PR2 may serve as channels of an NMOS transistor, and other one(s) thereof that may be close to the third power rail PR3 may serve as channels of a PMOS transistor.

In example embodiments, the first, second, third and sixth channels among the first to sixth channels in the first row region RG1 may have relatively large widths, and the fourth and fifth channels may have relatively small widths. The seventh and eighth channels among the seventh to twelfth channels in the second row region RG2 may have relatively small widths, and the ninth to twelfth channels may have relatively large widths.

In example embodiments, the first to sixth channels in the first to sixth transistor regions TR1, TR2, TR3, TR4, TR5 and TR6, respectively, may have different widths from each other, and the seventh to twelfth channels in the seventh to twelfth transistor regions TR7, TR8, TR9, TR10, TR11 and TR12, respectively, may have different widths from each other. In an example embodiment, a PMOS region and an NMOS region in the first to twelfth transistor regions TR1, TR2, TR3, TR4, TR5, TR6, TR7, TR8, TR9, TR10, TR11 and TR12 may have different widths from each other.

Thus, the layout of the sixth standard cell SC6 may be designed such that at least the clock inverter CKINV and the first and second output drivers ODRV1 and ODRV2 included in the first and second flip-flops FF1 and FF2 may be formed in the high performance transistor region. Additionally, the layout of the sixth standard cell SC6 may be designed such that the scan enable inverter SEINV, the input multi-flexer IMUXs, the first and second master latches ML1 and ML2, and the first and second slave latches SL1 and SL2 may have desired performed depending on the consumer's needs.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device, comprising:
first and second active patterns on a substrate, each of the first and second active patterns extending in a first direction, and the first and second active patterns being spaced apart from each other in a second direction crossing the first direction;
a first gate structure extending in the second direction on the first and second active patterns;
first channels spaced apart from each other in a third direction, perpendicular to the first and second directions, on the first active pattern, each of the first channels extending through the first gate structure in the first direction;
second channels spaced apart from each other in the third direction on the second active pattern, each of the second channels extending through the first gate structure in the first direction;
a first source/drain layer on the first active pattern at each of opposite sides in the first direction of the first gate structure, the first source/drain layer contacting the first channels and having a first conductivity type; and
a second source/drain layer on the second active pattern at each of opposite sides in the first direction of the first gate structure, the second source/drain layer contacting the second channels and having a second conductivity type opposite to the first conductivity type,
wherein a width in the second direction of each of the first channels is different from a width in the second direction of each of the second channels.

2. The semiconductor device as claimed in claim 1, wherein the first conductivity type is one of an n-type and a p-type, and the second conductivity type is the other of the n-type and the p-type.

3. The semiconductor device as claimed in claim 2, wherein the width in the second direction of each of the first channels is less than the width in the second direction of each of the second channels.

4. The semiconductor device as claimed in claim 2, wherein the width in the second direction of each of the first channels is greater than the width in the second direction of each of the second channels.

5. The semiconductor device as claimed in claim 2, further comprising:
a second gate structure extending in the second direction on the first and second active patterns, the second gate structure being spaced apart from the first gate structure in the first direction;
third channels spaced apart from each other in the third direction on the first active pattern, each of the third channels extending through the second gate structure in the first direction;
fourth channels spaced apart from each other in the third direction on the second active pattern, each of the fourth channels extending through the second gate structure in the first direction;
a third source/drain layer on the first active pattern at each of opposite sides in the first direction of the second gate structure, the third source/drain layer having the first conductivity type; and
a fourth source/drain layer on the second active pattern at each of opposite sides in the first direction of the second gate structure, the fourth source/drain layer having the second conductivity type.

6. The semiconductor device as claimed in claim 5, wherein a width in the second direction of each of the third channels is different from a width in the second direction of each of the fourth channels.

7. The semiconductor device as claimed in claim 5, wherein the width in the second direction of each of the first channels is substantially equal to the width in the second direction of each of the third channels, and the width in the second direction of each of the second channels is substantially equal to the width in the second direction of each of the fourth channels.

8. The semiconductor device as claimed in claim 5, wherein the width in the second direction of each of the first channels is substantially equal to the width in the second direction of each of the third channels, and the width in the second direction of each of the second channels is different from the width in the second direction of each of the fourth channels.

9. The semiconductor device as claimed in claim 5, wherein the width in the second direction of each of the first channels is different from the width in the second direction of each of the third channels, and the width in the second direction of each of the second channels is substantially equal to the width in the second direction of each of the fourth channels.

10. The semiconductor device as claimed in claim 5, wherein the first and third source/drain layers between the first and second gate structures are the same, and the second and fourth source/drain layers between the first and second gate structures are the same.

11. The semiconductor device as claimed in claim 2, wherein a ratio of a smallest one of widths in the second direction of the first and second channels with respect to a largest one thereof is equal to or less than 3.

12. The semiconductor device as claimed in claim 2, wherein widths in the second direction of the first and second channels are equal to or less than 50 nm.

13. A semiconductor device, comprising:
a first active pattern extending in a first direction on a substrate;
first and second gate structures spaced apart from each other in the first direction on the first active pattern;
first channels spaced apart from each other, in a third direction perpendicular to an upper surface of the substrate, on a first portion of the first active pattern, each of the first channels extending through the first gate structure in the first direction and having a first width in a second direction crossing the first direction;
second channels spaced apart from each other in the third direction on a second portion of the first active pattern, each of the second channels extending through the second gate structure in the first direction and having a second width in the second direction, and the second width being different from the first width;
a first source/drain layer at each of opposite sides in the first direction of the first gate structure, the first source/drain layer being connected with the first channels and having a first conductivity type; and
a second source/drain layer at each of opposite sides in the first direction of the second gate structure, the second source/drain layer being connected with the second channels and having the first conductivity type.

14. The semiconductor device as claimed in claim 13, wherein the first and second source/drain layers between the first and second gate structures are the same.

15. The semiconductor device as claimed in claim 13, further comprising a second active pattern spaced apart from the first active pattern in the second direction, the second active pattern extending in the first direction,
wherein each of the first and second gate structures extends in the second direction, and is formed on the second active pattern.

16. The semiconductor device as claimed in claim 15, further comprising:
third channels spaced apart from each other in the third direction on a first portion of the second active pattern, each of the third channels extending through the first gate structure in the first direction and having a third width in the second direction;
fourth channels spaced apart from each other in the third direction on a second portion of the second active pattern, each of the fourth channels extending through the second gate structure in the first direction and having a fourth width in the second direction;
a third source/drain layer at each of opposite sides in the first direction of the first gate structure, the third source/drain layer being connected with the third channels and having a second conductivity type opposite to the first conductivity type; and
a fourth source/drain layer at each of opposite sides in the first direction of the second gate structure, the fourth source/drain layer being connected with the fourth channels and having the second conductivity type.

17. The semiconductor device as claimed in claim 16, wherein the third width is different from the first width.

18. The semiconductor device as claimed in claim 16, wherein the fourth width is different from the second width.

19. A semiconductor device, comprising:
first and second active patterns on a substrate, each of the first and second active patterns extending in a first direction, and the first and second active patterns being spaced apart from each other in a second direction crossing the first direction;
a first gate structure extending in the second direction on the first and second active patterns;
first channels spaced apart from each other in a third direction, perpendicular to the first and second directions, on the first active pattern, each of the first channels extending through the first gate structure in the first direction and having a first width in the second direction;
second channels spaced apart from each other in the third direction on the second active pattern, each of the second channels extending through the first gate structure in the first direction and having a second width in the second direction different from the first width;
a first source/drain layer on a portion of the first active pattern at each of opposite sides in the first direction of the first gate structure, the first source/drain layer contacting the first channels and having a first conductivity type;
a second source/drain layer on a portion of the second active pattern at each of opposite sides in the first direction of the first gate structure, the second source/drain layer contacting the second channels and having a second conductivity type opposite to the first conductivity type;
a first contact plug on the first gate structure;
a second contact plug on the first source/drain layer;
a third contact plug on the second source/drain layer; and
first, second and third wirings electrically connected to the first, second and third contact plugs, respectively.

20. The semiconductor device as claimed in claim 19, further comprising:
a second gate structure extending in the second direction on the first and second active patterns, the second gate structure being spaced apart from the first gate structure in the first direction;
third channels spaced apart from each other in the third direction on the first active pattern, each of the third channels extending through the second gate structure in the first direction and having a third width in the second direction;
fourth channels spaced apart from each other in the third direction on the second active pattern, each of the fourth channels extending through the second gate structure in the first direction and having a fourth width in the second direction different from the third width;
a third source/drain layer on a portion of the first active pattern at each of opposite sides in the first direction of the second gate structure, the third source/drain layer having the first conductivity type; and
a fourth source/drain layer on a portion of the second active pattern at each of opposite sides in the first direction of the second gate structure, the fourth source/drain layer having the second conductivity type.
